(19) United States
(12) Patent Application Publication
(10) Pub. No.: US 2014/0061757 A1
(43) Pub. Date: Mar. 6, 2014

(54) SEMICONDUCTOR DEVICES AND METHODS OF FABRICATING THE SAME

(71) Applicants: SUNGGIL KIM, Yongin-si (KR); Sunghoi Hur, Seoul (KR); Jung-Hwan Kim, Seoul (KR); HongSuk Kim, Yongin-si (KR); Guk-Hyon Yon, Hwaseong-si (KR); JaeHo Choi, Busan (KR)

(72) Inventors: SUNGGIL KIM, Yongin-si (KR); Sunghoi Hur, Seoul (KR); Jung-Hwan Kim, Seoul (KR); HongSuk Kim, Yongin-si (KR); Guk-Hyon Yon, Hwaseong-si (KR); JaeHo Choi, Busan (KR)

(21) Appl. No.: 13/971,279

(22) Filed: Aug. 20, 2013

(30) Foreign Application Priority Data
Sep. 6, 2012 (KR) 10-2012-0098897

(51) Int. Cl. H01L 29/788; H01L 29/66

(52) U.S. Cl. CPC H01L 29/788; H01L 29/66825
USPC 257/316; 438/259

(57) ABSTRACT

A semiconductor device includes a semiconductor substrate having a plurality of active regions defined by a trench. A gate electrode crosses the plurality of active regions. A plurality of charge storing cells is disposed between the gate electrode and each of the plurality of active regions. A porous insulating layer is disposed between the gate electrode and the plurality of charge storing cells. The porous insulating layer includes a portion extended over the trench. An air gap is disposed between the extended portion of the porous insulating layer and a bottom surface of the trench.

### CROSS-REFERENCE TO RELATED APPLICATION

This application claims priority under 35 U.S.C. §119 to Korean Patent Application No. 10-2012-0098897, filed on Sep. 6, 2012, in the Korean Intellectual Property Office, the disclosure of which is incorporated by reference herein in its entirety.

### TECHNICAL FIELD

The present inventive concept relate to a semiconductor device and a method of fabricating the same, and in particular, to a semiconductor device with an air gap and a method of fabricating the same.

### DISCUSSION OF RELATED ART

High speed and reliable semiconductor memory devices are in demand. As integration density of semiconductor devices is ever increasing, various materials and device structures have been proposed to reduce signal interference among elements of semiconductor devices.

### SUMMARY

According to an exemplary embodiment of the inventive concept, a semiconductor device is provided. The semiconductor device includes a semiconductor substrate having a plurality of active regions defined by a trench. A gate electrode crosses the plurality of active regions. A plurality of charge storing cells is disposed between the gate electrode and each of the plurality of active regions. A porous insulating layer is disposed between the gate electrode and the plurality of charge storing cells. The porous insulating layer includes a portion extended over the trench. An air gap is disposed between the extended portion of the porous insulating layer and a bottom surface of the trench.

According to an exemplary embodiment of the inventive concept, a semiconductor device is provided. The semiconductor device includes a semiconductor substrate having a trench. A porous insulating layer is disposed on the semiconductor substrate. The porous insulating layer extending over the trench defines an air gap in the trench underneath the porous insulating layer. A gate electrode is disposed on the porous insulating layer.

According to an exemplary embodiment of the inventive concept, a semiconductor device is provided. The semiconductor device includes a semiconductor substrate including a plurality of lower wires extended in a first direction. A plurality of semiconductor patterns is disposed on each of the plurality of lower wires. The plurality of semiconductor patterns is spaced apart from each other along the first direction. A porous insulating layer is disposed top surfaces of the plurality of semiconductor patterns and covers an air gap between two adjacent semiconductor patterns of the plurality of semiconductor patterns. A plurality of lower electrodes is disposed on the porous insulating layer. The plurality of lower electrodes respectively penetrates the porous insulating layer to be in contact with the plurality of semiconductor patterns. A plurality of memory elements is respectively disposed on the plurality of lower electrodes. Each of the plurality of memory elements is extended in a second direction crossing the first direction.

According to an exemplary embodiment of the inventive concept, a semiconductor device is provided. The semiconductor device includes a semiconductor substrate. The semiconductor substrate includes a first trench and a second trench. A first insulation layer is disposed on the semiconductor substrate. A first air gap is disposed in the first trench and is covered by a first porous insulation layer. A second air gap is disposed in the second trench and covered by the first porous insulation layer. A non-volatile memory cell is disposed on an active region between the first trench and the second trench. Each of the first and second air gaps partially and laterally overlaps the non-volatile memory cell.

According to an exemplary embodiment of the inventive concept, a fabrication method is provided. In the fabrication method, a trench is formed in a semiconductor substrate to define a plurality of active regions. A sacrificial layer is formed in the trench. A porous insulating layer is formed on the plurality of active regions and sacrificial layer. The porous insulating layer includes a plurality of pores. An air gap is formed in the trench by removing the sacrificial layer through the plurality of pores of the porous insulating layer. The air gap is covered by the porous insulating layer. A gate electrode is fanned on the porous insulating layer.

### BRIEF DESCRIPTION OF THE DRAWINGS

These and other features of the inventive concept will become more apparent by describing in detail exemplary embodiments thereof with reference to the accompanying drawings of which:

FIG. 1 is a plan view illustrating a semiconductor device according to an exemplary embodiment of the inventive concept;

FIGS. 2 through 11 are sectional views taken along lines I-I′ and II-II′ of FIG. 1 to illustrate a method of fabricating a semiconductor device according to an exemplary embodiment of the inventive concept;

FIG. 12 is a perspective view of a semiconductor device fabricated by a method according to an exemplary embodiment of the inventive concept;

FIGS. 13 and 14 are enlarged views of portions A and B, respectively, of FIG. 12;

FIG. 15 is an enlarged view of the portion B of FIG. 12 that illustrates a semiconductor device according to an exemplary embodiment of the inventive concept;

FIGS. 16 through 17 are sectional views taken along lines I-I′ and II-II′ of FIG. 1 to illustrate a method of fabricating a semiconductor device according to an exemplary embodiment of the inventive concept;

FIG. 18 is a perspective view of a semiconductor device fabricated by a method according to an exemplary embodiment of the inventive concept;

FIGS. 19 through 26 are sectional views taken along lines I-I′ and II-II′ of FIG. 1 to illustrate a method of fabricating a semiconductor device according to an exemplary embodiment of the inventive concept;

FIG. 27 is a perspective view of a semiconductor device fabricated by a method according to an exemplary embodiment of the inventive concept;

FIG. 28 is an enlarged view of a portion C of FIG. 27;

FIGS. 29 through 33 are sectional views taken along lines I-I′ and II-II′ of FIG. 1 to illustrate a method of fabricating a semiconductor device according to an exemplary embodiment of the inventive concept;

FIGS. 34 through 42 are plan and sectional views illustrating a semiconductor device and a method of fabricating the same according to an exemplary embodiment of the inventive concept;

FIG. 43 is a perspective view illustrating a semiconductor device fabricated by a method according to an exemplary embodiment of the inventive concept;

FIG. 44 is an enlarged view of a portion D of FIG. 43;

FIGS. 45 through 48 are perspective views illustrating a method of fabricating a semiconductor device according to an exemplary embodiment of the inventive concept;

FIG. 49 is a block diagram illustrating an example of electronic systems including a semiconductor device according to an exemplary embodiment of the inventive concept;

FIG. 50 is a block diagram illustrating an exemplary memory card including a semiconductor memory device according to an exemplary embodiment of the inventive concept; and

FIG. 51 is a block diagram illustrating an exemplary information processing system including a semiconductor device according to an exemplary embodiment of the inventive concept.

### DETAILED DESCRIPTION OF EXEMPLARY EMBODIMENTS

Exemplary embodiments of the inventive concept will be described below in detail with reference to the accompanying drawings. However, the inventive concept may be embodied in different forms and should not be construed as limited to the embodiments set forth herein. In the drawings, the thickness of layers and regions may be exaggerated for clarity. It will also be understood that when a layer is referred to as being “on” another layer or substrate, it may be directly on the other layer or substrate, or intervening layers may also be present. Like reference numerals may refer to the like elements throughout the specification and drawings.

It will be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of an exemplary embodiment.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

As used herein, singular “a,” “an” and “the” are intended to include the plural forms as well, unless the context clearly indicates otherwise.

An exemplary embodiment of the inventive concepts are described herein with reference to cross-sectional illustrations that are schematic illustrations of idealized embodiments (and intermediate structures) of an exemplary embodiment. As such, variations from the shapes of the illustrations as a result, for example, of manufacturing techniques and/or tolerances, are to be expected. Thus, an exemplary embodiment of the inventive concepts should not be construed as limited to the particular shapes of regions illustrated herein but is to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of an exemplary embodiment.

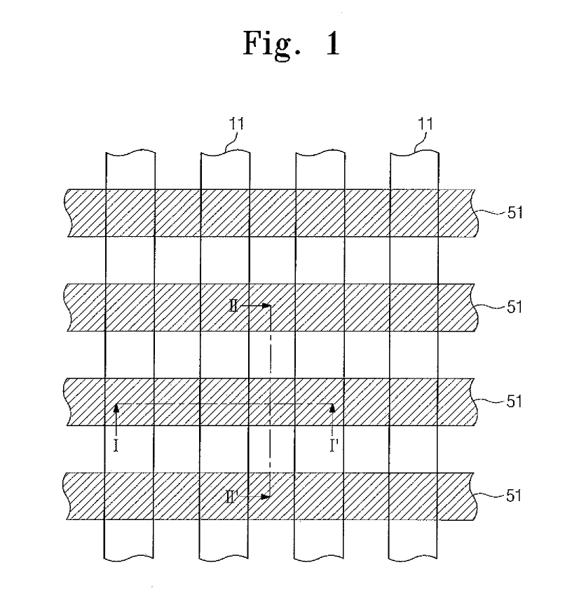

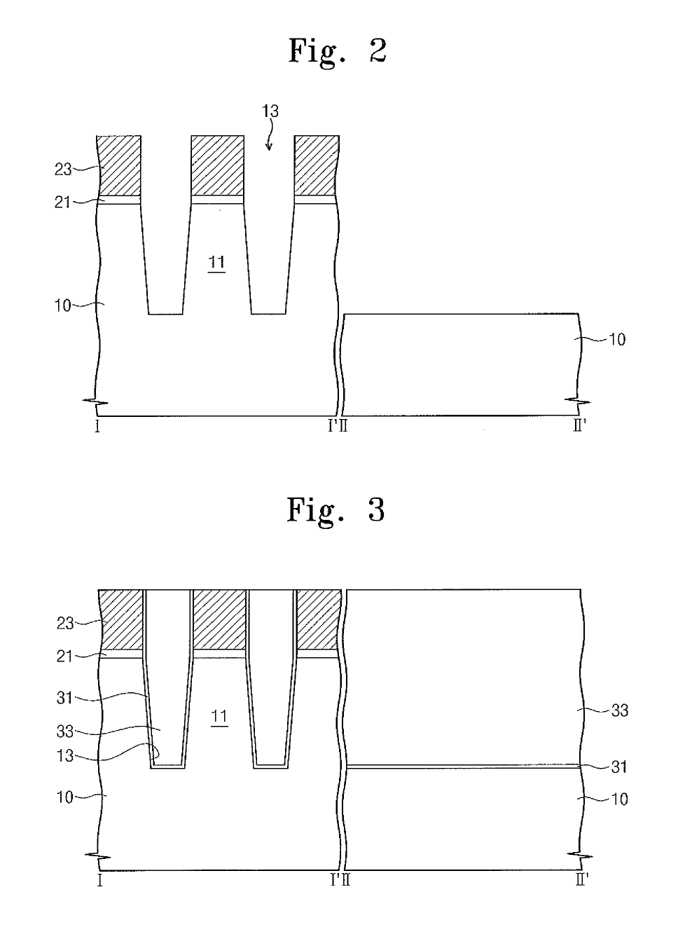

FIG. 1 is a plan view illustrating a semiconductor device according to an exemplary embodiment of the inventive concept. FIGS. 2 through 11 are sectional views taken along lines I-I′ and II-II′ of FIG. 1 to illustrate a method of fabricating a semiconductor device according to an exemplary embodiment of the inventive concept.

Referring to FIGS. 1 and 2, a trench 13 may be formed in a semiconductor substrate 10 to define a tunnel insulating pattern 21, a floating gate pattern 23 and an active region 11.

In an exemplary embodiment, the formation of the trench 13 may include forming a tunnel insulating layer and a floating gate conductive layer on the semiconductor substrate 10, forming a mask pattern (not shown) on the floating gate conductive layer, anisotropically and sequentially etching the tunnel insulating layer, the floating gate conductive layer and the semiconductor substrate 10 using the mask pattern as an etch mask.

The semiconductor substrate 10 may include a bulk silicon wafer, a silicon-on-insulator (SOI) wafer, a germanium wafer, a germanium-on-insulator (GOI) wafer, a silicon-germanium wafer, or a substrate including an epitaxial layer grown by a selective epitaxial growth (SEG) process.

The tunnel insulating layer may include, for example, a silicon oxide layer (SiO₂) formed by a thermal oxidation process. Alternatively, the tunnel insulating layer may include a high-k dielectric material (e.g., Al₂O₃, HfO₂, ZrO₂, La₂O₃, Ta₂O₃, TiO₂, SrTiO₃ (STO), or (Ba,Sr)TiO₃ (BST)), and be provided in a form of a single-layered or multilayered structure. The tunnel insulating layer may be formed using a chemical vapor deposition (CVD) process or an atomic layer deposition (ALD) process.

The floating gate conductive layer may be formed by depositing a polysilicon layer on the tunnel insulating layer. In an exemplary embodiment, during the deposition of the polysilicon layer, impurities such as phosphorus or boron may be doped into the polysilicon layer. In an exemplary embodiment, the floating gate conductive layer may include a conductive material (e.g., metal silicide, metal nitride, or metal) having a work-function higher than that of the doped polysilicon.

The trench 13 may be shaped like a line, when viewed from a plan view, and have a downward tapered sidewall profile in a sectional view. For example, a width of the trench 13 is smaller at a lower portion thereof than at an upper portion thereof. The trench 13 may have an aspect ratio of about 2 or more. The aspect ratio of the trench 13 may be increased with increasing an integration density of the semiconductor device.

As the result of the anisotropic etching process to form the trench 13, the tunnel insulating pattern 21 and the floating gate pattern 23 may be formed on the active region 11 of the semiconductor substrate 10. The tunnel insulating pattern 21 and floating gate pattern 23 may be formed using the patterning process for forming the line-shaped active region 11, and may have a line shape. After the formation of the trench 13, the mask pattern may be removed from a top surface of the floating gate pattern 23.

Referring to FIG. 3, an insulating liner 31 may be formed on an inner surface of the trench 13. An insulating gap-filling layer 33 may be formed on the insulating liner 31 to fill the trench 13.

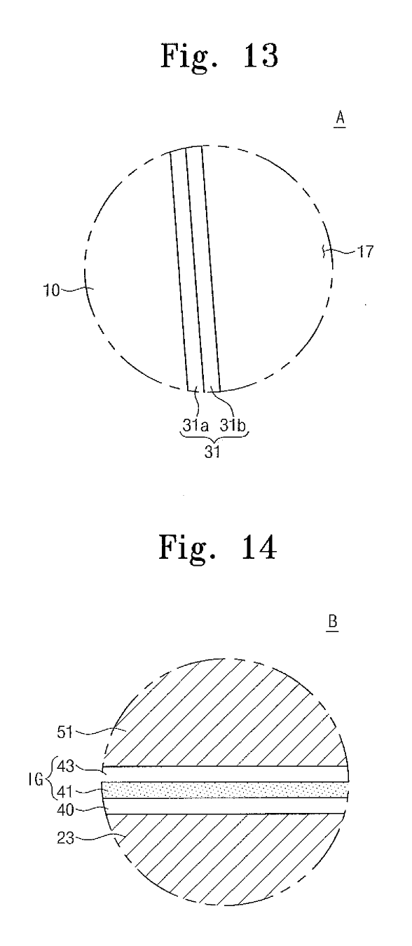

The insulating liner 31 may conformally cover the trench 13. The formation of the insulating liner 31 may include sequentially forming an oxide liner (e.g., 31a of FIG. 13) and a nitride liner (e.g., 31b of FIG. 13).

The oxide liner may be formed by a thermal oxidation process. Thermal oxidation process may be performed on an exposed inner surface of the trench 13 by a dry oxidation using O₂ or a wet oxidation using H₂O. The formation of the oxide liner may serve to cure and/or reduce defects (e.g., dangling bonds) on the inner surface of the trench 13 and damage caused by the anisotropic etching process.

The nitride liner may prevent the oxide liner between the insulating gap-filling layer 33 and the semiconductor substrate 10 from thickening. The nitride liner may prevent the insulating gap-filling layer 33 filling the trench 13 from being expanded, and thus reduce a stress to be exerted on the inner surface of the trench 13.

The insulating liner 31 may be formed using a deposition technique with a good step coverage property, such as a CVD process or an ALD process.

The insulating gap-filling layer 33 may fill an inner space of the trench 13 and an empty space between the floating gate patterns 23. The insulating gap-filling layer 33 may include an insulating material with a good gap-filling property. The insulating gap-filling layer 33 may include an insulating material having a good gap-filling property, such as boron-phosphor silicate glass (BPSG), high density plasma (HDP) oxide, O₃-TEOS, undoped silicate glass (USG), or Tonen SilaZene (TOSZ). Furthermore, the insulating gap-filling layer 33 may be formed using thin film-forming techniques having a good step-coverage property. For example, the insulating gap-filling layer 33 may be formed using deposition methods, such as a CVD process, a sub-atmospheric CVD (SA-CVD) process, a low pressure CVD (LP-CVD) process, a plasma enhanced CVD (PE-CVD) process or a physical vapor deposition (PVD) process.

In an exemplary embodiment, the insulating gap-filling layer 33 may include a Tonen Silazane (TOSZ) layer. The TOSZ layer may include a polysilazane layer. The TOSZ layer may be formed using a spin-coating method. For example, the formation of the TOSZ layer may include performing a spin-coating process, supplying O₂ and H₂O to the resulting structure, and performing an annealing process to remove ammonia and hydrogen from the TOSZ layer. In this case, the TOSZ layer may include a silicon oxide layer.

Thereafter, a planarization process (for example, a chemical mechanical polishing (CMP) process) may be performed to planarize top surfaces of the structure provided with the insulating liner 31 and the insulating gap-filling layer 33. For example, as the result of the planarization process, top surfaces of the insulating liner 31 and the insulating gap-filling layer 33 may be coplanar with a top surface of the floating gate pattern 23.

Referring to FIG. 4, an upper portion of the insulating gap-filling layer 33 may be recessed to form an insulating gap-filling pattern 35 filling a lower portion of the trench 13.

The recess of the insulating gap-filling layer 33 may be performed using an etch-back process. The insulating gap-filling pattern 35 may have a concave top surface, as shown in FIG. 4. The insulating gap-filling pattern 35 may have the top surface lower than the top surface of the active region 11 of the semiconductor substrate 10. During the etch-back process, a portion of the insulating liner 31 may be removed from sidewalls of the floating gate pattern 23 and the tunnel insulating pattern 21.

During the recess of the upper portion of the insulating gap-filling layer 33, edge portions of the floating gate pattern 23 may be etched to have rounded corners. Accordingly, the floating gate pattern 23 may have an upwardly-convex top surface and an upper width of the floating gate pattern 23 may be smaller than a lower width thereof.

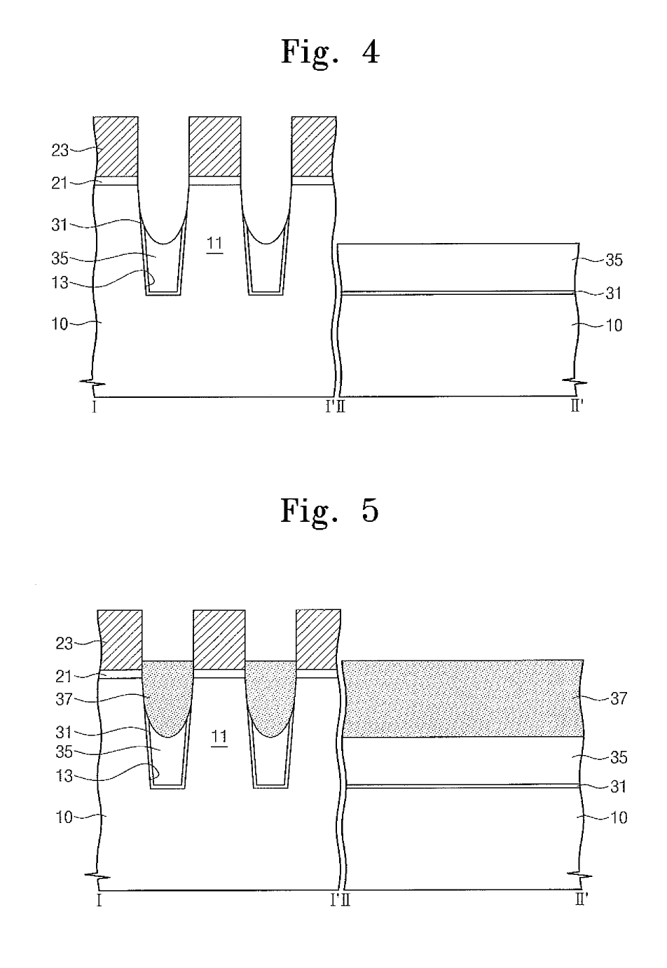

Referring to FIG. 5, a first sacrificial layer 37 may be formed on the insulating gap-filling pattern 35 to fill the upper portion of the trench 13.

The first sacrificial layer 37 may be formed using a spin-coating technique to fill a space between the floating gate patterns 23, and then, it may be etched back to have a recessed top surface. In an exemplary embodiment, the top surface of the first sacrificial layer 37 may be higher than that of the tunnel insulating pattern 21. According to an exemplary embodiment of the inventive concept, the vertical height of the first sacrificial layer 37 may determine a volume of an air gap to be fanned in a subsequent process.

The first sacrificial layer 37 may include a material having etch selectivity with respect to the insulating gap-filling pattern 35 and the floating gate pattern 23. In an exemplary embodiment, the first sacrificial layer 37 may include a carbon-based material. For example, the first sacrificial layer 37 may include carbon and hydrogen atoms, or may include carbon, hydrogen and oxygen atoms. In an exemplary embodiment, the first sacrificial layer 37 may include a relatively high carbon concentration of about 80-99 weight percent.

In an exemplary embodiment, the first sacrificial layer 37 may include a spin-on-hardmask (SOH) layer or an amorphous carbon layer (ACL). The SOH layer may include a carbon-based SOH layer or a silicon-based SOH layer. In an exemplary embodiment, the first sacrificial layer 37 may include a photoresist layer or an amorphous silicon layer.

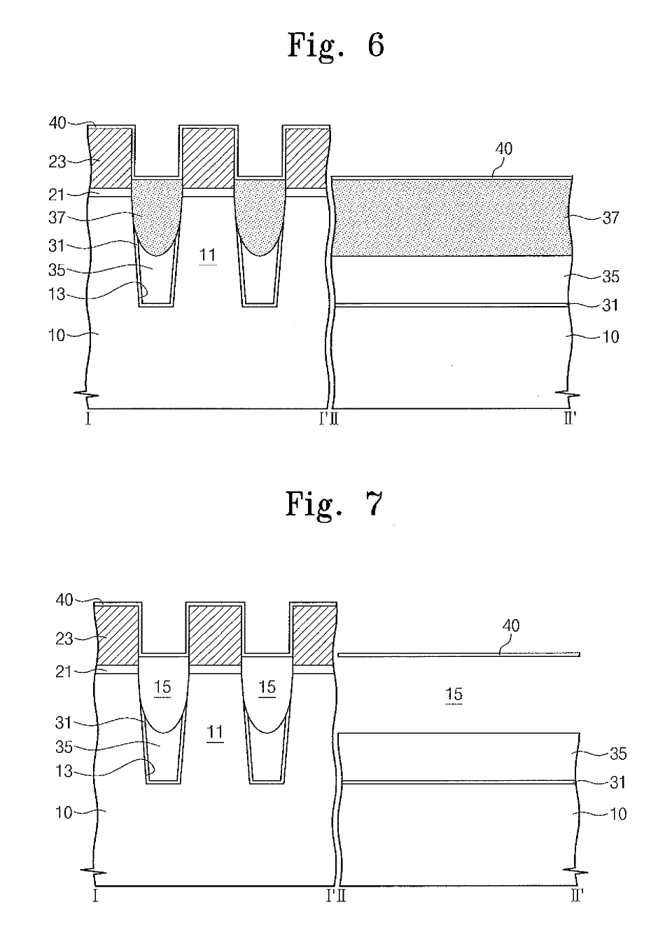

Referring to FIG. 6, a first porous insulating layer 40 may be formed on the first sacrificial layer 37.

The first porous insulating layer 40 may conformally cover top surfaces of the first sacrificial layer 37 and the floating gate pattern 23.

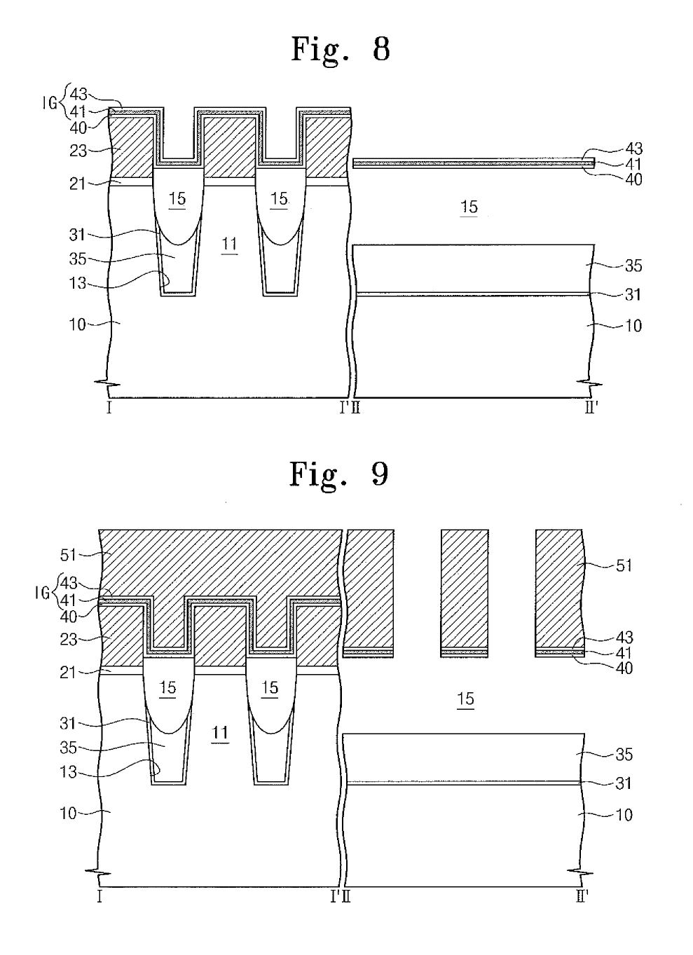

The first porous insulating layer 40 may include an insulating layer with a plurality of pores. The first porous insulating layer 40 may include a porous low-k dielectric material. The first porous insulating layer 40 may be formed by, for example, forming a carbon-doped silicon oxide layer including carbon atoms and performing a thermal treatment thereto. As the result of thermal treatment, the carbon atoms in the carbon-doped silicon oxide layer may be combined with silicon atoms to form a cage-like structure, and thus the first porous insulating layer 40 may have a lower density than SiO₂. The silicon oxide layer having the cage-like structure may include a SiCOH layer. The SiCOH layer may include trimethylsilane (3MS, (CH₃)₃—Si—H), tetramethylsilane (4MS, (CH₃)₄—Si), or vinyltrimethylsilane (VTMS, CH₂═CH—Si (CH₃)₃) as a precursor. An oxygen-containing oxidant gas (e.g., hydrogen peroxide) may be used for oxidizing the precursor. The carbon-doped silicon oxide layer may be formed using a PECVD process or an ALD process. The carbon-doped silicon oxide layer may be converted into the first porous insulating layer 40 (e.g., p-SiCOH) by a thermal treatment process. Alternatively, the first porous insulating layer 40 may be formed by forming a porous silicon layer and thermally treating the porous silicon layer. The first porous insulating layer 40 may include a plurality of pores whose a size or a diameter ranges from several ten nanometers to several hundred nanometers. The first porous insulating layer 40 may have porosities of 5-50 volume percentage (vol. %). In a subsequent wet etching process using an HF etching solution, an etch rate of the first porous insulating layer 40 may be greater than an etch rate of an inter-gate insulating layer (for example, IG of FIG. 8) to be formed subsequently. For example, the first porous insulating layer 40 may have an etch rate of about 100 to 200 Å/min, when the first porous insulating layer 40 is etched using a 200:1 dilute HF solution.

Referring to FIG. 7, the first sacrificial layer 37 may be removed by using the 1.5 pores of the first porous insulating layer 40. In the case where the first sacrificial layer 37 includes an SOH layer or a photoresist layer, the removal of the first sacrificial layer 37 may be performed using an ashing process, in which oxygen, ozone, or ultra violet (UV) light is used, or using a wet cleaning process. For example, in the case where the first sacrificial layer 37 includes an SOH layer, the removal of the first sacrificial layer 37 may be performed using a fluorine-based etching gas mixed with O₂ gas or with O₂ gas and Ar gas. Here, the fluorine-based etching gas may include C₃F₆, C₄F₆, C₄F₈, or C₅F₈. In the case where the first sacrificial layer 37 includes an amorphous silicon layer, the removal of the first sacrificial layer 37 may be performed by an isotropic etching process using a chlorine-containing gas.

As the result of the removal of the first sacrificial layer 37, a first air gap 15 may be formed below the first porous insulating layer 40. The first air gap 15 may be delimited by the top surface of the insulating gap-filling pattern 35, the sidewall of the trench 13 and the bottom surface of the first porous insulating layer 40. For example, the first air gap 15 may be formed between the active regions 11 of the semiconductor substrate 10. According to an exemplary embodiment of the inventive concept, a vertical level of the first air gap 15 may be determined by that of the first sacrificial layer 37, and thus, if the first sacrificial layer 37 is sufficiently thick and has the upper surface thereof between the floating gate patterns 23, the first air gap 15 may be disposed between the floating gate patterns 23. In an exemplary embodiment, the first air gap 15 may be filled with air having lower permittivity than insulating layers (e.g., silicon oxide), and thus may serve to reduce electrical interference or coupling capacitance between the active regions 11 or between the floating gate patterns 23.

In an exemplary embodiment, after the formation of the first air gap 15, a densification process may be performed on the first porous insulating layer 40. The densification process may be performed using a rapid thermal treatment process. For example, during the rapid thermal treatment process, the first porous insulating layer 40 may be heated to a temperature of about 800° C. to about 1000° C. in an atmosphere of N₂O, NO, N₂, H₂O or O₂. As the result of the densification process, the first porous insulating layer 40 provided with the pores may have an increased density. For example, the size or the number of the pores may be reduced.

Referring to FIG. 8, an inter-gate insulating layer IG may be formed on the first porous insulating layer 40.

The inter-gate insulating layer IG may include a material having a higher dielectric constant than the tunnel insulating pattern 21. For example, the inter-gate insulating layer IG may be formed to have a single or multi-layered structure including a silicon oxide layer, a silicon nitride layer, or high-k materials (such as, Al₂O₃, HfO₂, ZrO₂, La₂O₃, Ta₂O₃, TiO₂, SrTiO₃ (STO), or (Ba,Sr)TiO₃ (BST)). In an exemplary embodiment, the inter-gate insulating layer IG may include a first dielectric layer 41 and a second dielectric layer 43 that are sequentially stacked. The first dielectric layer 41 may include a material whose dielectric constant is different from that of the second dielectric 43. For example, the inter-gate insulating layer IG may include a silicon nitride layer and a silicon oxide layer that are sequentially stacked on the first porous insulating layer 40.

The inter-gate insulating layer IG may be conformally formed on the first porous insulating layer 40. The inter-gate insulating layer IG may be formed using a deposition process, such as a CVD process, a SA-CVD process, an LP-CVD process, a PE-CVD process or a PVD process.

Referring to FIGS. 1 and 9, a control gate electrode 51 may be formed to cross the active region 11. The control gate electrode 51 may be formed to fill a gap between the floating gate patterns 23.

For example, the formation of the control gate electrode 51 may include forming a control gate conductive layer on the inter-gate insulating layer IG, forming a mask pattern (not shown) on the control gate conductive layer to cross the active region 11, sequentially and anisotropically etching the floating gate pattern 23, the inter-gate insulating layer IG and the control gate conductive layer using the mask pattern as an etch mask.

The control gate conductive layer may be formed by depositing a polysilicon layer on the inter-gate insulating layer IG. During the deposition of the polysilicon layer, dopants such as phosphorus or boron may be doped into the polysilicon layer. Alternatively, the control gate conductive layer may include a conductive material (for example, metal silicide, metal nitride, or metal) having a higher work-function than the doped polysilicon layer.

As the result of the anisotropic etching process to form the control gate electrode 51, the tunnel insulating pattern 21 and the floating gate pattern 23 may be locally formed on the active region 11. For example, the floating gate patterns 23 may be spaced apart from each other, on the active region 11 of the semiconductor substrate 10. The tunnel pattern 21 and the floating gate pattern 23 may constitute a charge storing cell.

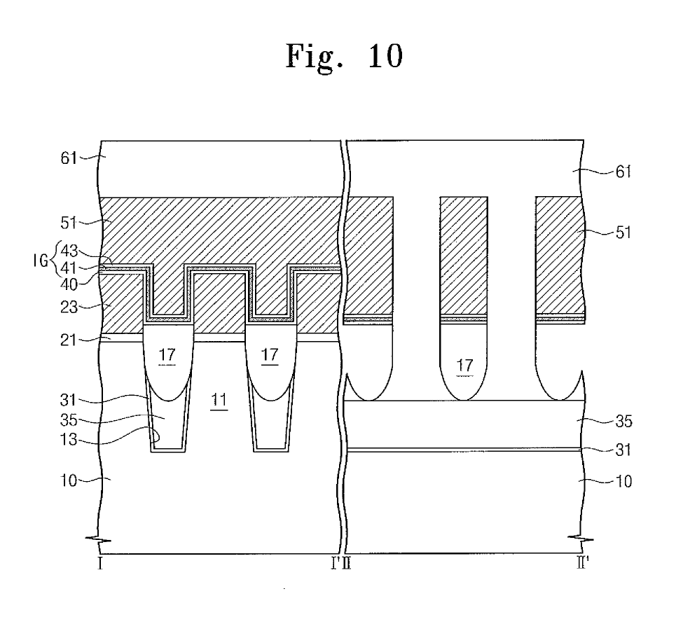

Referring to FIG. 10, an interlayered insulating layer 61 may be formed on the semiconductor substrate 10 provided with the floating gate pattern 23 and the control gate electrodes 51 to form a second air gap 17.

In an exemplary embodiment, the interlayered insulating layer 61 may include an insulating layer having a low step coverage property and/or using a deposition process having a low step coverage property. The interlayered insulating layer 61 may be a silicon oxide layer. The interlayered insulating layer 61 may be formed to fill a space provided between gate structures, each of which includes the floating gate pattern 23, the inter-gate insulating layer 61 and the control gate electrode 51.

In an exemplary embodiment, the interlayered insulating layer 61 may be formed to fill a portion of the first air gap, which may be exposed by the anisotropic etching process for forming the control gate electrode 51 and the floating gate pattern 23. However, other portion of the first air gap which is located below the first porous insulating layer 40 between the floating gate patterns 23 need not be filled with the interlayered insulating layer 61. Accordingly, the second air gap 17 may be formed below the first porous insulating layer 40. The second air gap 17 may be delimited by the sidewall of the trench 13 and the sidewall of the interlayered insulating layer 61.

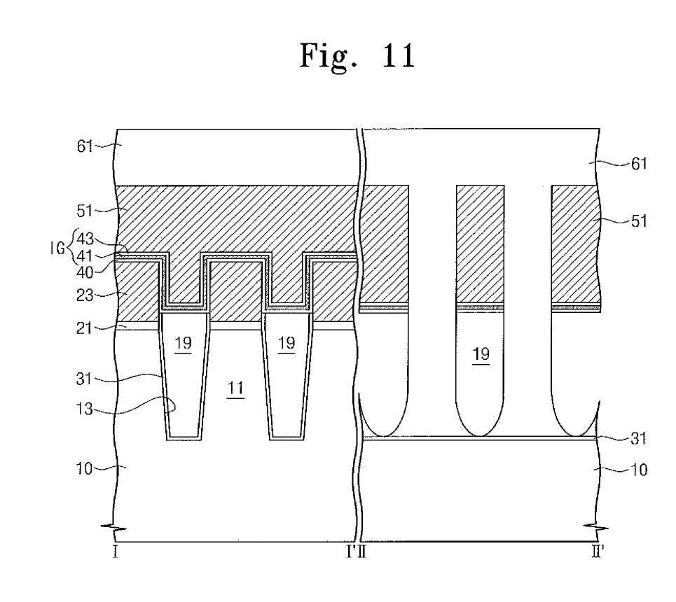

According to an exemplary embodiment of the inventive concept, the step of forming the insulating gap-filling pattern 35 described with reference to FIGS. 3 and 4 may be omitted. For example, after forming the insulating liner 31 on the inner surface of the trench 13, the first sacrificial layer 37 described with reference to FIG. 5 may fill the trench 13. Accordingly, the first sacrificial layer 37 may be in direct contact with the insulating liner 31 that is provided at the bottom surface of the trench 13. Afterwards, the subsequent processes may be performed to form an air gap 19 exposing the insulating liner 31 formed on the inner surface of the trench 13, as shown in FIG. 11. The air gap 19 of FIG. 11 may have a height greater than that of the air gap 17 described with reference to FIG. 10.

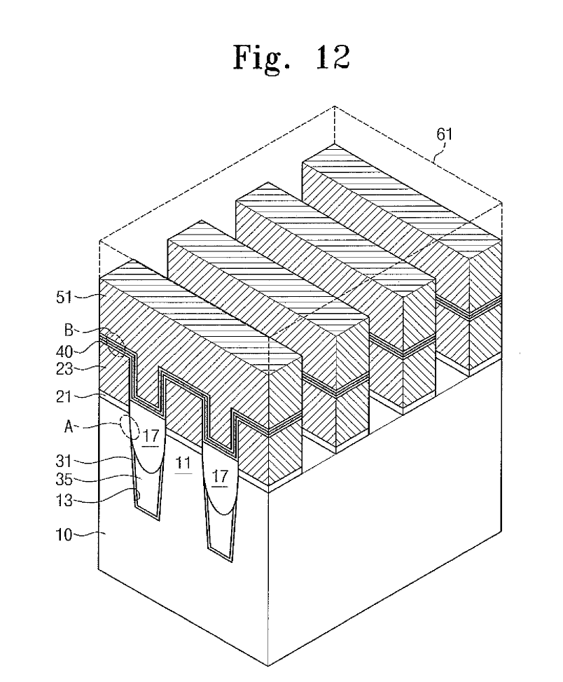

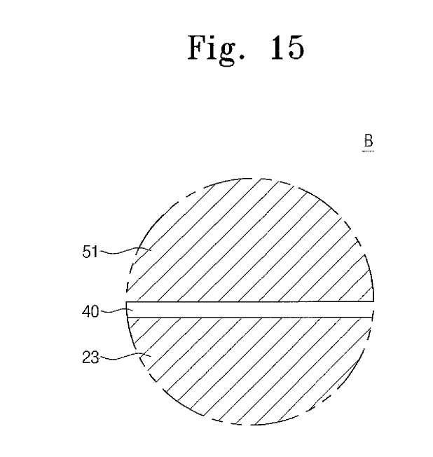

FIG. 12 is a perspective view of a semiconductor device fabricated by a method according to an exemplary embodiment of the inventive concept. FIGS. 13 and 14 are enlarged views of portions A and B, respectively, of FIG. 12, and FIG. 15 is an enlarged view of the portion B of FIG. 12.

Hereinafter, a semiconductor device, which may be fabricated by a method according to an exemplary embodiment of the inventive concept, will be described with reference to FIGS. 12 through 15.

Referring to FIG. 12, a trench 13 defining active regions 11 is formed in a semiconductor substrate 10. The trench 13 defines the active regions 11 and has a line shape. The trenches 13 are spaced apart from each other and are extended parallel to each other.

A gate structure may be provided on the semiconductor substrate 10. The gate structure may include a tunnel insulating pattern 21, a floating gate pattern 23, an inter-gate insulating layer IG and a control gate electrode 51 that are sequentially stacked on the semiconductor substrate 10.

For example, the tunnel insulating pattern 21 may be formed on the active region 11 of the semiconductor substrate 10. In nonvolatile memory devices, programming and erasing operations may be performed using an F-N tunneling of electric charges, which may occur through the tunnel insulating pattern 21.

The floating gate pattern 23 may be locally formed on the active regions 11. For example, a plurality of the floating gate patterns 23 may be spaced apart from each other on the active region 11. Each of the floating gate patterns 23 may have a sloped sidewall, and thus, the floating gate pattern 23 may have a lower width greater than an upper width. The floating gate pattern 23 may include a polysilicon layer doped with n-type or p-type impurities. The floating gate pattern 23 may serve to store electric charges which tunneled through the tunnel insulating pattern 21.

The inter-gate insulating layer IG may serve to electrically separate the floating gate pattern 23 from the control gate electrode 51. The inter-gate insulating layer IG may cover top surfaces of the floating gate patterns 23 adjacent thereto. For example, an upper portion of the floating gate pattern 23 may be conformally covered with the inter-gate insulating layer IG. In an exemplary embodiment, the inter-gate insulating layer IG may cover a top surface and both side surfaces of the floating gate pattern 23. This enables to increase a contact area between the floating gate pattern 23 and the inter-gate insulating layer IG, and thus, it increases a coupling ratio between the control gate electrode 51 and the floating gate pattern 23. In an exemplary embodiment, the inter-gate insulating layer IG may include a first dielectric layer and a second dielectric layer stacked in a sequential manner. Here, the first dielectric layer may include a material whose permittivity is different from that of the second dielectric. The first and second dielectric layers may have a permittivity higher than that of the tunnel insulating pattern 21. For example, the inter-gate insulating layer IG may include a silicon nitride layer and a silicon oxide layer stacked in a sequential manner.

The control gate electrode 51 may cross the active regions 11. The control gate electrode 51 may be disposed between the floating gate patterns 23. For example, a bottom surface of the control gate electrode 51 between the floating gate patterns 23 may be lower than a top surface of the floating gate pattern 23. The control gate electrode 51 may serve to control electric potential of the floating gate pattern 23 when the nonvolatile memory device is operated. Since the control gate electrode 51 includes a portion disposed between two adjacent floating gate patterns 23, interference between the two adjacent floating gate patterns 23 may be reduced.

In an exemplary embodiment, an air gap 17 may be disposed in the trench 13 between the active regions 11. For example, a top surface of the air gap 17 may be delimited by a bottom surface of a porous insulating layer between two adjacent floating gate patterns 23. The porous insulating layer 40 may cross the active regions 11. The bottom surface of the porous insulating layer 40 between the two floating gate patterns 23 is lower than the top surface of the floating gate pattern 23 between the active regions 11. The porous insulating layer 40 may include a dielectric film including a plurality of pores whose size or diameter is about several ten nanometers. For example, the porous insulating layer 40 may be a silicon oxide layer or a p-SiCOH layer. In an exemplary embodiment, the porous insulating layer 40 may be in direct contact with the floating gate pattern 23 and the inter-gate insulating layer 1G, as shown in FIG. 14. Alternatively, as shown in FIG. 15, the porous insulating layer 40 may be in direct contact with the control gate electrode 51, without the inter-gate insulating layer IG interposed therebetween.

In an exemplary embodiment, a bottom surface of the air gap 17 may be delimited by a top surface of an insulating gap-filling pattern 35 filling a lower portion of the trench 13. Furthermore, an insulating liner 31 may be disposed between sidewalls of the insulating gap-filling pattern 35 and the trench 13. The insulating liner 31 may include a silicon oxide layer 31a which covers an inner surface of the trench 13 and a silicon nitride layer 31b disposed on the silicon oxide layer 31a, as shown in FIG. 13. The insulating liner 31 disposed on the sidewall of the trench 13 may be exposed by the air gap 17.

In an exemplary embodiment, the air gap 17 may be disposed between the insulating gap-filling pattern 35 and the porous insulating layer 40, and thus, the air gap 17 may have a height corresponding to a vertical space between the insulating gap-filling pattern 35 and the porous insulating layer 40. An overlap area between the inter-gate insulating layer IG and the floating gate pattern 23 may vary depending on the height of the air gap 17 formed in the trench 13. For example, a coupling ratio between the control gate electrode 51 and the floating gate pattern 23 may be determined by the height of the air gap 17 formed in the trench 13.

In an exemplary embodiment, the top surface of the porous insulating layer 40 between two adjacent floating gate patterns 23 may be lower than the top surface of the floating gate pattern 23, and this configuration may increase an overlap area between the floating gate pattern 23 and the control gate electrode 51. Accordingly, the coupling ratio between the control gate electrode 51 and the floating gate pattern 23 may increase when FLASH memory devices operate. The air gap 17 is filled with air having lower permittivity than a silicon oxide layer, and thus a coupling capacitance between two adjacent active regions 11 may be reduced. Accordingly, electrical interference or disturbance between memory cells may be reduced.

In an exemplary embodiment, the bottom surface of the air gap 17 may be delimited by the insulating liner 31 disposed on the bottom surface of the trench 13, as shown in FIG. 11. In this case, the air gap 17 may have a height greater than that of the previous embodiment described with reference to FIG. 12.

An insulating layer may be formed on the semiconductor substrate 10 provided with the gate structures. The insulating layer may be disposed on the semiconductor substrate 10 to fill a gap between the gate structures. Here, the insulating layer may fill a portion of the trench 13 between the control gate electrodes 51. However, the air gap 17 positioned below the control gate electrode 51 need not be filled with the insulating layer.

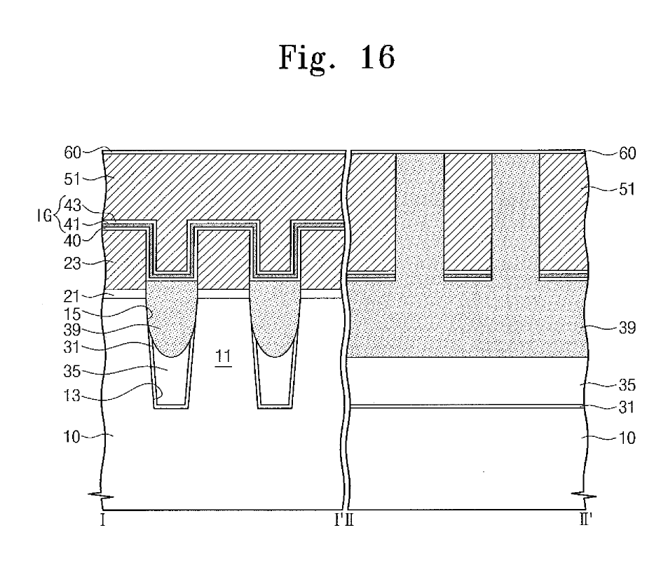

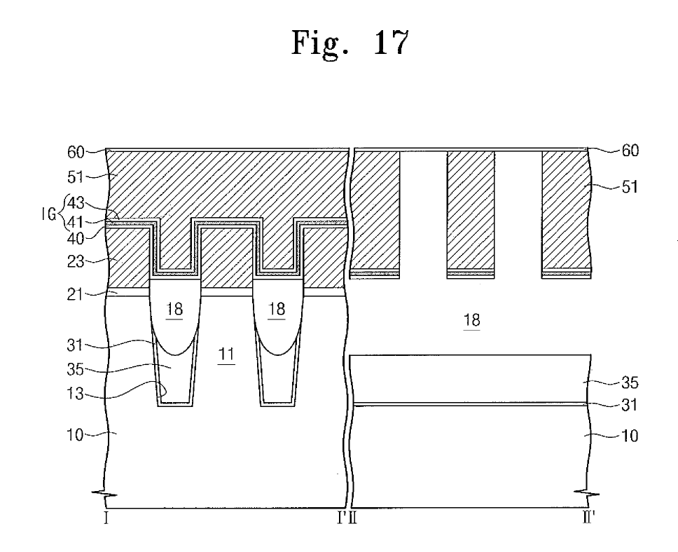

FIGS. 16 through 17 are sectional views taken along lines I-I′ and II-II′ of FIG. 1 to illustrate a method of fabricating a semiconductor device according to an exemplary embodiment of the inventive concept.

According to an exemplary embodiment, gate structures may be formed on the semiconductor substrate 10 according to a fabrication method which is substantially the same as that as described with reference to FIGS. 1 through 9, and then a second sacrificial layer 39 may be formed to fill the first air gap 15 and a gap between the gate structures as shown in FIG. 16. Each of gate structures may be formed to include the floating gate pattern 23, the inter-gate insulating layer IG and the control gate electrode 51.

The second sacrificial layer 39 may include a material having etch selectivity with respect to the insulating gap-filling pattern 35 and the gate structures. The second sacrificial layer 39 may include the same material as the first sacrificial layer 37 described with reference to FIG. 5. A planarization process may be performed on the second sacrificial layer 39 to expose top surfaces of the control gate electrodes 51. A top surface of the second sacrificial layer 39 may be coplanar with a top surface of the control gate electrode 51.

Thereafter, as shown in FIG. 16, a second porous insulating layer 60 may be formed on the top surfaces of the second sacrificial layer 39 and the control gate electrode 51. The second porous insulating layer 60 may be formed using substantially the same process as that for forming the first porous insulating layer 40 described with reference to FIG. 6. As a result, the second porous insulating layer 60 may be formed to include a plurality of pores.

Referring to FIG. 17, the second sacrificial layer 39 may be selectively removed through the pores of the second porous insulating layer 60. The removal of the second sacrificial layer 39 may be performed using substantially the same method as that for removing the first sacrificial layer 40 described with reference to FIG. 7. As the result of the removal of the second sacrificial layer 39, a third air gap 18 may be formed between the active regions 11 and between the gate structures. In an exemplary embodiment, the third air gap 18 may be delimited by a top surface of the insulating gap-filling pattern 35, a sidewall of the trench 13, a bottom surface of the first porous insulating layer 40, a sidewall of the floating gate patterns 23, a sidewall of the control gate electrodes 51 and a bottom surface of the second porous insulating layer 60.

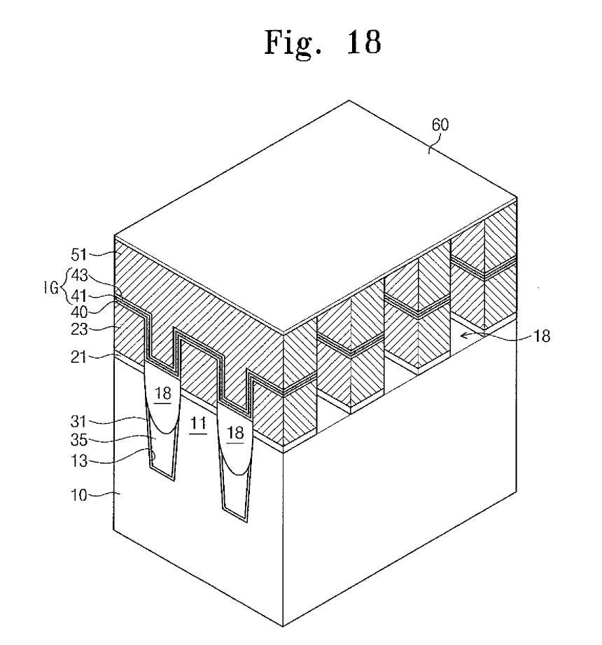

FIG. 18 is a perspective view of a semiconductor device fabricated by a method according to an exemplary embodiment of the inventive concept.

Referring to FIG. 18, a semiconductor device may include the semiconductor substrate 10 provided with the trench 13 and the active regions 11 defined by the trench 13, as described with reference to FIG. 12. The trench 13 may define the active regions 11 having a line shape and being spaced apart from and parallel to each other. A gate structure may be disposed on the semiconductor substrate 10. The gate structure may include a tunnel insulating pattern 21, a floating gate pattern 23, an inter-gate insulating layer IG and a control gate electrode 51 that are sequentially stacked on the semiconductor substrate 10.

In an exemplary embodiment, an air gap 18 is disposed in the trench 13. The air gap 18 may include a line-shaped empty space disposed between the active regions 11 and an empty space disposed between the control gate electrodes 51. For example, the air gap 18 may be formed between the active regions 11 below the first porous insulating layer 40 and between the control gate electrodes 51 below the second porous insulating layer 60.

FIGS. 19 through 26 are sectional views taken along lines I-I′ and II-II′ of FIG. 1 to illustrate a method of fabricating a semiconductor device according to an exemplary embodiment of the inventive concept. A semiconductor device according to an exemplary embodiment may include a NAND FLASH memory device having a charge trap insulating layer.

Referring to FIG. 19, a tunnel insulating pattern 22, a charge trap pattern 26, and a blocking insulating pattern 28 may be formed on a semiconductor substrate 10. A trench 12 may define an active region 11 of the semiconductor substrate 10. For example, the trench 12 is formed in the substrate 10, penetrating the tunnel insulating pattern 22, the charge trap pattern 26, and the blocking insulating pattern 28.

The formation of the trench 12 may include sequentially stacking a tunnel insulating layer, a charge trap layer, and a blocking insulating layer on the semiconductor substrate 10, forming a mask pattern 30 on the blocking insulating layer, sequentially and anisotropically etching the blocking insulating layer, the charge trap layer, the tunnel insulating layer, and the semiconductor substrate 10 using the mask pattern 30 as an etch mask. The tunnel insulating layer, the charge trap layer, and the blocking insulating layer may be farmed using a CVD or ALD process. The mask pattern 30 may include a photoresist pattern, a silicon nitride layer, or a dual layer including a silicon oxide layer and a silicon nitride layer.

The tunnel insulating pattern 22 may be, for example, a silicon oxide layer (SiO₂), which may be formed by thermally oxidizing a top surface of the semiconductor substrate 10. Alternatively, the tunnel insulating layer may include a high-k dielectric (e.g., metal oxide) material. The charge trap pattern 26 may include a silicon nitride layer, a silicon oxynitride layer, a Si-rich nitride layer, a nano-crystalline Si layer, or a laminated layer thereof. The blocking insulating pattern 28 may include a material having an energy band gap greater than the charge trap pattern 26. For example, the blocking insulating pattern 28 may include a high-k metal oxide layer and in certain embodiments, the blocking insulating pattern 28 may further include a silicon oxide layer.

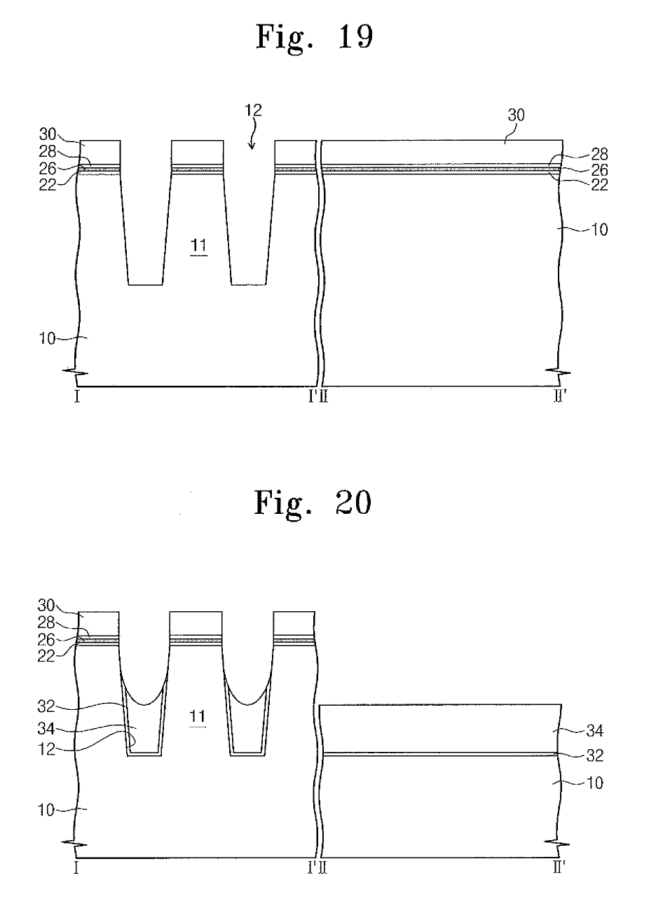

Referring to FIG. 20, an insulating liner 32 and an insulating gap-filling layer may be sequentially formed in the trench 12, as described with reference to FIG. 3. Thereafter, the insulating gap-filling layer may be recessed to form an insulating gap-filling pattern 34 located in a lower portion of the trench 12, as described with reference to FIG. 4. Accordingly, a sidewall of the trench 12 may be partially exposed.

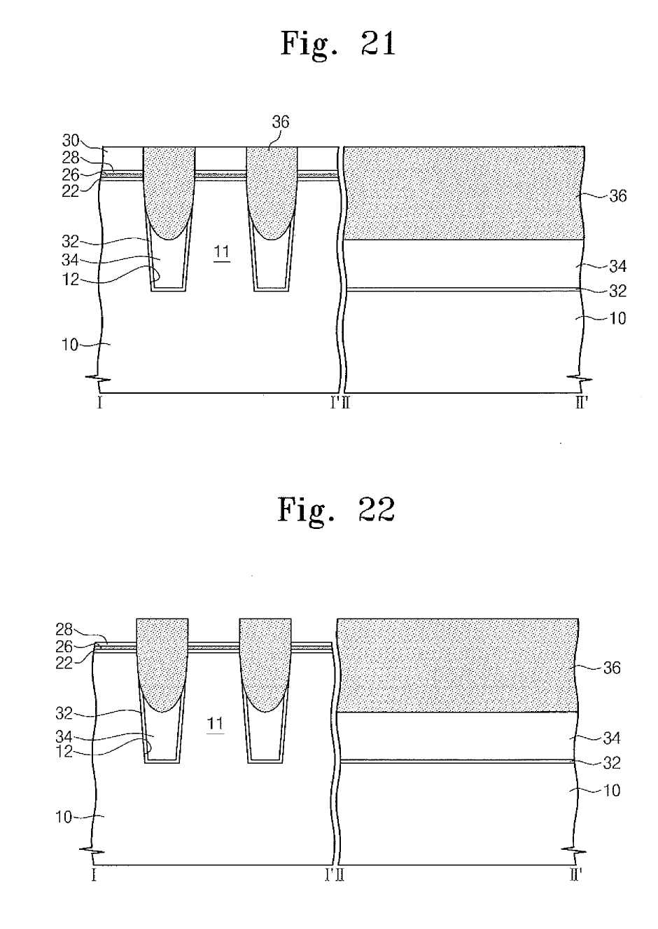

Referring to FIG. 21, a first sacrificial layer 36 may be formed on the insulating gap-filling pattern 34 and fills the trench 12. The first sacrificial layer 36 may include a material having etch selectivity with respect to the tunnel insulating pattern 22, the charge trap pattern 26, the blocking insulating pattern 28, and the mask pattern 30. The first sacrificial layer 36 may include an SOH layer or an amorphous carbon layer, as described with reference to FIG. 5. The SOH layer may include a carbon-based SOH layer or a silicon-based SOH layer. Alternatively, the first sacrificial layer 36 may include a photoresist layer or an amorphous silicon layer.

The first sacrificial layer 36 may be formed using a spin-coating method to fill a gap between the mask patterns 30, and then, a planarization process may be performed to the first sacrificial layer 36 to expose a top surface of the mask pattern 30.

Referring to FIG. 22, the mask pattern 30 may be removed to expose the top surface of the blocking insulating pattern 28. Accordingly, an upper portion of the first sacrificial layer 36 may protrude upward between two adjacent active regions 11. Accordingly, the top surface of the blocking insulating pattern 28 may be lower than the top surface of the first sacrificial layer 36.

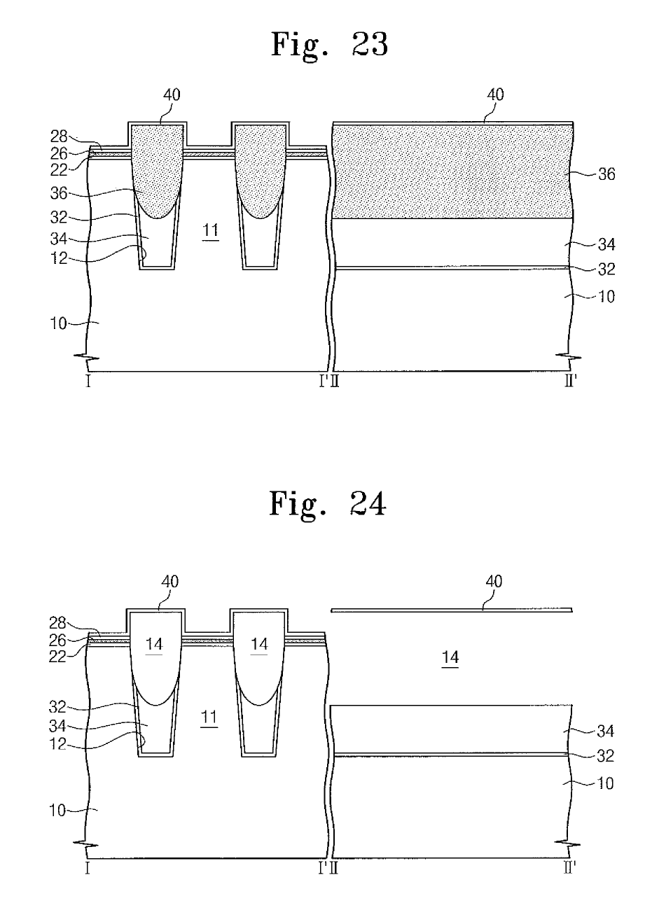

Referring to FIG. 23, a first porous insulating layer 40 may be formed to cover an exposed surface of the first sacrificial layer 36. The first porous insulating layer 40 may also cover the top surface of the blocking insulating pattern 28.

The first porous insulating layer 40 may include an insulating layer having a plurality of pores therein, as described with reference to FIG. 6. For example, the first porous insulating layer 40 may include a porous low-k dielectric layer. The first porous insulating layer 40 may be formed by, for example, forming a carbon-doped silicon oxide layer and performing a thermal treatment thereon. In an exemplary embodiment, the first porous insulating layer 40 may include a p-SiCOH layer. The first porous insulating layer 40 may include a plurality of pores whose a size or a diameter ranges from several ten nanometers to several hundred nanometers. The first porous insulating layer 40 may have porosities of 5-50 vol. %. In a subsequent wet etching process using an HF etching solution, the first porous insulating layer 40 may have an etch rate greater than those of the tunnel insulating pattern 22, the charge trap pattern 24, and the blocking insulating pattern 28. For example, the first porous insulating layer 40 may have an etch rate of about 100 to about 200 Å/min, when the first porous insulating layer 40 is etched using a 200:1 dilute HF solution.

Referring to FIG. 24, the first sacrificial layer 36 may be removed by using the pores of the first porous insulating layer 40.

As described with reference to FIG. 7, in the case where the first sacrificial layer 36 includes an SOH layer or a photoresist layer, the removal of the first sacrificial layer 36 may be performed using an ashing process, in which oxygen, ozone, or UV light is used, or using a wet cleaning process. After the removal of the first sacrificial layer 36, the first porous insulating layer 40 may remain on the blocking insulating pattern 28.

As the result of the removal of the first sacrificial layer 36, an air gap 14 may be formed between the active regions 11, and between layer stacks including the tunnel insulating pattern 22, the charge trap pattern 26 and the blocking insulating pattern 28. The air gap 14 may be delimited by the top surface of the insulating gap-filling pattern 34, the sidewall of the trench 12, and the bottom surface of the first porous insulating layer 40. The tunnel insulating pattern 22, the charge trap pattern 26 and the blocking insulating pattern 28 may have sidewalls exposed by the air gap 14.

After the formation of the air gap 14, a densification process may be performed to the first porous insulating layer 40 in a rapid thermal treatment process.

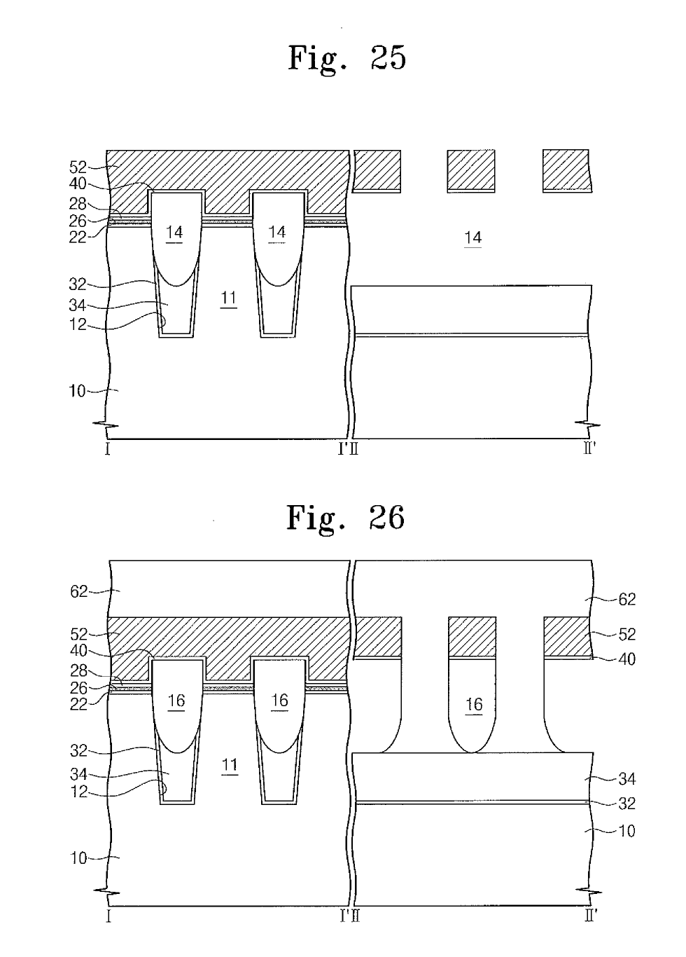

Referring to FIG. 25, gate electrodes 52 may be formed on the first porous insulating layer 40 to cross the active regions 11.

For example, the formation of the gate electrode 52 may include forming a gate conductive layer on the first porous insulating layer 40, forming a mask pattern (not shown) on the gate conductive layer to cross the active region 11, sequentially and anisotropically etching the first porous insulating layer 40, the blocking insulating pattern 28, the charge trap pattern 26, the tunnel insulating pattern 22, and the gate conductive layer using the mask pattern as an etch mask. Accordingly, the tunnel insulating pattern 22, the charge trap pattern 26, and the blocking insulating pattern 28 may be locally formed on the active region 11, and the trench 12 may be exposed between the gate electrodes 52.

Referring to FIG. 26, an interlayered insulating layer 62 may be formed between the gate electrodes 52. The interlayered insulating layer 62 may include an insulating layer having a low step coverage property and/or using a deposition process having a low step coverage property. The interlayered insulating layer 62 may fill a portion of the first air gap 14 between two adjacent gate electrodes 52, but other portion of the first porous insulating layer 40 need not be filled with the interlayered insulating layer 62. Accordingly, an empty space 16 may be formed under the gate electrodes 52. The empty space 16 may be referred to as a second air gap 16.

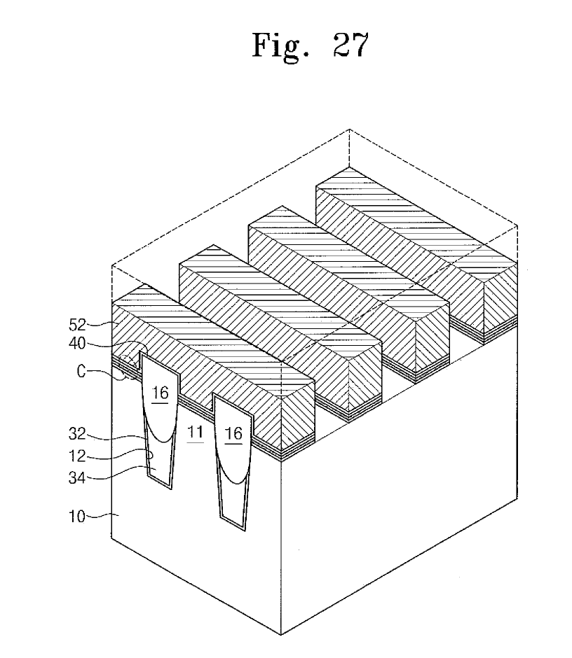

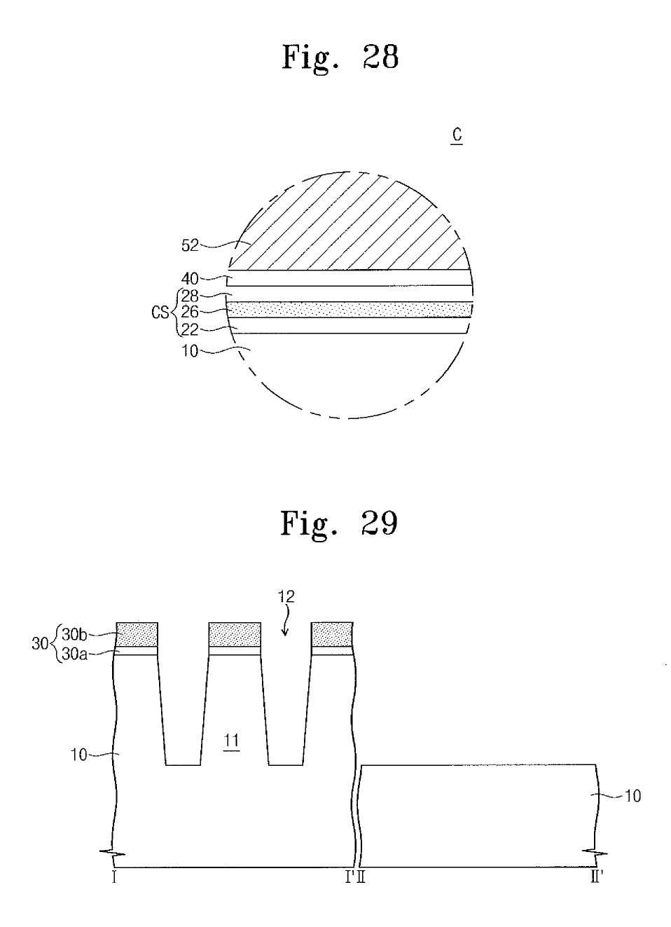

FIG. 27 is a perspective view of a semiconductor device fabricated by a method according to an exemplary embodiment of the inventive concept. FIG. 28 is an enlarged view of a portion C of FIG. 27.

Referring to FIGS. 27 and 28, a semiconductor device according to an exemplary embodiment may include a semiconductor substrate 10, in which a trench 12 is formed to define active regions 11. The trenches 12 may have a line shape and are spaced apart from and parallel to each other. A gate electrode 52 may be disposed on the semiconductor substrate 10 to cross the active regions 11. A charge storing pattern CS may be disposed between the gate electrode 52 and the active region 11. The charge storing pattern may constitute a charge storing cell.

In an exemplary embodiment, the charge storing pattern CS may include a tunnel insulating pattern 22, a charge trap pattern 26 and a blocking insulating pattern 28 that are sequentially stacked on the active region 11. In an exemplary embodiment, the charge storing pattern CS may include a charge trap layer, which may include a silicon nitride layer, a silicon oxynitride layer, a Si-rich nitride layer, a nano-crystalline silicon structure, or a laminated layer thereof.

The first porous insulating layer 40 may be disposed between the charge storing pattern CS and the gate electrode 52. The first porous insulating layer 40 is also disposed over the trench 12, thereby defining a top surface of an air gap 18. In an exemplary embodiment, in a region of the trench 12, the top surface of the first porous insulating layer 40 may be disposed on the top surface of the charge storing pattern CS. The gate electrode 52 may be in direct contact with the top surface of the first porous insulating layer 40.

The first porous insulating layer 40 interposed between the charge storing pattern CS and the gate electrode 52 may include a material that prevents leakage of electric charges stored in the charge storing pattern CS or a back-tunneling problem. For example, the first porous insulating layer 40 may include a silicon oxide layer and/or a high-k dielectric material having a plurality of pores therein.

According to an exemplary embodiment of the inventive concept, the air gap 16 may be formed to expose the sidewall of the charge storing pattern CS. A height of the air gap 16 may correspond to a vertical distance between the top surface of the insulating gap-filling pattern 34 and the bottom surface of the first porous insulating layer 40.

FIGS. 29 through 33 are sectional views taken along lines I-I′ and II-II′ of FIG. 1 to illustrate a method of fabricating a semiconductor device according to an exemplary embodiment of the inventive concept.

Referring to FIG. 29, a mask pattern 30 may be formed on a semiconductor substrate 10 to define active regions 11. The mask pattern 30 may include a silicon oxide layer pattern 30a and a silicon nitride layer pattern 30b that are sequentially stacked on the semiconductor substrate 10. Alternatively, the mask pattern 30 may include a photoresist layer. Thereafter, the mask pattern 30 may be used to etch the semiconductor substrate 10 and form a trench 12 in the semiconductor substrate 10. The trench 12 may include a line shape extending along a direction.

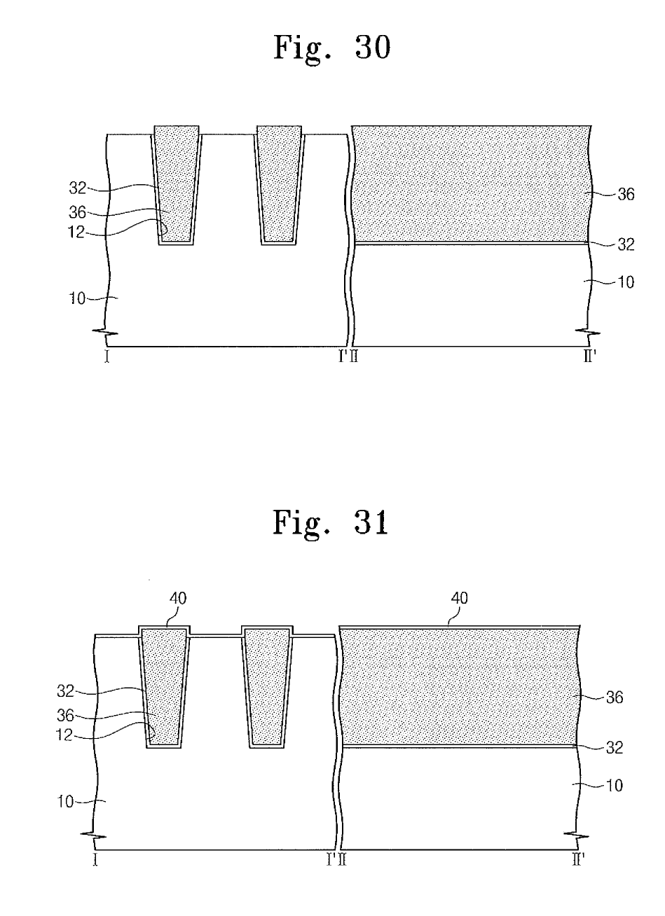

Referring to FIG. 30, a sacrificial layer 36 may be formed to fill the trench 12. The sacrificial layer 36 may include a SOH layer or an amorphous carbon layer, as described with reference to FIG. 5. The SOH layer may include a carbon-based SOH layer or a silicon-based SOH layer. Alternatively, the sacrificial layer 36 may include a photoresist layer or an amorphous silicon layer.

An insulating liner 32 may be formed before the formation of the sacrificial layer 36, as described with reference to FIG. 3. In an exemplary embodiment, an insulating gap-filling pattern (e.g., see 35 of FIG. 4) may be formed to fill a lower portion of the trench 12, before the formation of the sacrificial layer 36.

After the formation of the sacrificial layer 36, the mask pattern 30 may be removed to expose the top surface of the active region 11 of the semiconductor substrate 10. The sacrificial layer 36 may protrude upward from the semiconductor substrate 10.

Referring to FIG. 31, a porous insulating layer 40 may be formed on the sacrificial layer 36. The porous insulating layer 40 may also be formed on the top surface of the semiconductor substrate 10. In an exemplary embodiment, a portion of the porous insulating layer 40 may be in direct contact with the top surface of the semiconductor substrate 10.

The porous insulating layer 40 may include an insulating layer having a plurality of pores, as described with reference to FIG. 6. For example, the porous insulating layer 40 may include a porous low-k dielectric layer. The formation of the porous insulating layer 40 may include forming a carbon-doped silicon oxide layer and then performing a thermal treatment process thereto. In an exemplary embodiment, the porous insulating layer 40 may include a p-SiCOH layer. The porous insulating layer 40 may include a plurality of pores whose a size or a diameter ranges from several ten nanometers to several hundred nanometers. The porous insulating layer 40 may have porosities of about 5 to about 50 vol. %. Further, in a wet etching process using an HF etching solution, the porous insulating layer 40 may have an etch rate greater than those of a charge trap layer 42 and a blocking insulating layer 44 to be formed subsequently. For example, the porous insulating layer 40 may have an etch rate of about 100 to about 200 Å/min, when the porous insulating layer 40 is etched using a 200:1 dilute HF solution.

Referring to FIG. 32, the sacrificial layer 36 may be removed using the pores of the porous insulating layer 40, thereby forming an air gap 16 between the active regions 11.

As described with reference to FIG. 7, in the case where the sacrificial layer 36 includes an SOH layer or a photoresist layer, the removal of the sacrificial layer 36 may be performed using an ashing process, in which oxygen, ozone, or UV light is used, or using a wet cleaning process.

After the formation of the air gap 16, a densification process may be performed to the porous insulating layer 40 to increase a film quality of the porous insulating layer 40. In an exemplary embodiment, the porous insulating layer 40 may define a top surface of the air gap 16 and is in direct contact with the top surface of the active region 11 of the semiconductor substrate 10. In this case, the porous insulating layer 40 may serve as a tunnel insulating layer.

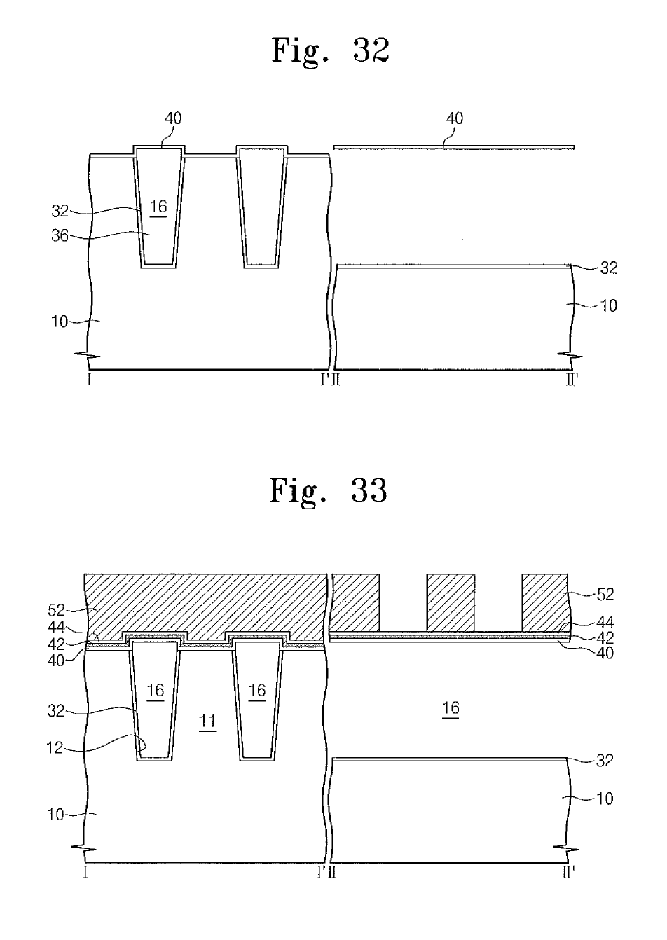

Referring to FIG. 33, a charge trap layer 42 and a blocking insulating layer 44 may be sequentially stacked on the porous insulating layer 40. Next, gate electrodes 52 may be formed on the blocking insulating layer 44 to cross the active regions 11. An anisotropic etching process may be performed to form the gate electrodes 52, and the blocking insulating layer 44 may serve as an etch stop layer in the anisotropic etching process. Accordingly, the air gap 16 need not be exposed below the porous insulating layer 40.

In an exemplary embodiment, a capping layer (not shown) may be further formed on the blocking insulating layer 44, before the formation of the gate electrodes 52. For example, the porous insulating layer 40, the charge trap layer 42, the blocking insulating layer 44 and the capping layer (not shown) may be sequentially interposed between the semiconductor substrate 10 and the gate electrode 52.

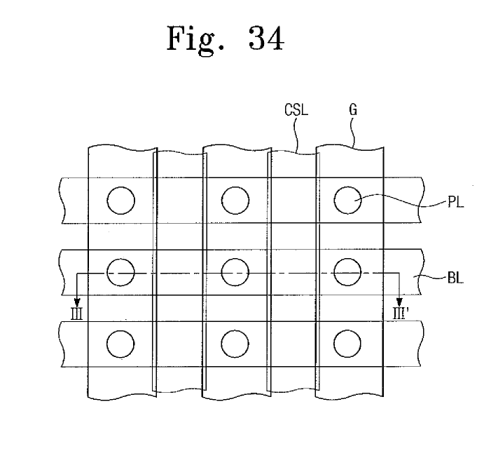

A semiconductor device and a method of fabricating the same according to an exemplary embodiment of the inventive concept will be described in detail with reference to FIGS. 34 through 42. The semiconductor device according to an exemplary embodiment may include a vertical-type NAND FLASH memory device.

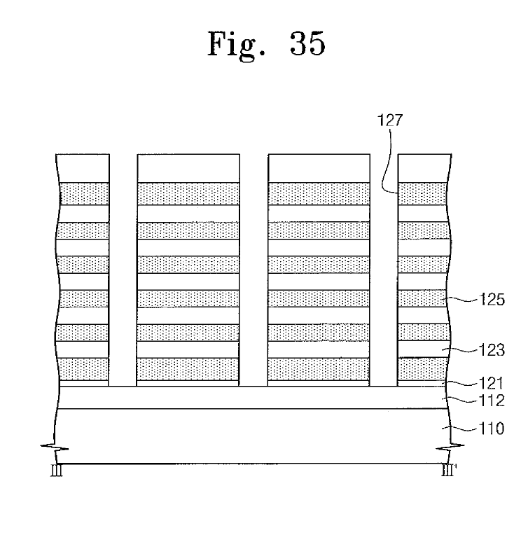

FIG. 34 is a plan view illustrating a method of fabricating a semiconductor device according to an exemplary embodiment of the inventive concept. FIGS. 35 through 42 are sectional views taken along line III-III′ of FIG. 34.

Referring to FIG. 34, gate electrode stacks G may extend in a first direction to be parallel with each other. Common source lines CSL may be disposed in a substrate below spaces between the gate electrode stacks G. Bit lines BL may extend in a second direction intersecting the first direction to run across the gate electrode stacks G. Active pillars PL may be located at respective ones of intersections that the gate electrode stacks G and the bit lines BL cross each other. The active pillars PL may extend in a direction perpendicular to the substrate. For example, the active pillars PL may extend in a direction perpendicular to the first and second directions.

Referring to FIG. 35, a substrate 110 may be provided. Impurity ions of a first conductivity type may be injected into the substrate 110 to form a well region 112. The well region 112 may be formed using an ion implantation process.

A buffer dielectric layer 121 may be formed on the substrate having the well region 112. The buffer dielectric layer 121 may include, for example, a silicon oxide layer. The buffer dielectric layer 121 may be formed using a thermal oxidation process. First material layers 123 and second material layers 125 may be alternately stacked on the buffer dielectric layer 121. One of the second material layers 125 may be formed directly on the buffer dielectric layer 121. For example, a lowermost material layer of the stacked material layers may include one of the second material layers 125. An uppermost material layer of the stacked material layers may include one of the first material layers 123. The lowermost and uppermost ones of the second material layers 125 may be thicker than the intermediate second material layers 125 therebetween. Each of the first material layers 123 may include an insulation layer. For example, each of the first material layers 123 may be formed to include a silicon oxide layer. Each of the second material layers 125 may be formed to include a material having a different wet etch rate from the first material layers 123. For example, the second material layers 125 may be formed to include a silicon nitride layer or a silicon oxynitride layer. The first and second material layers 123 and 125 may be formed using a chemical vapor deposition (CVD) process.

The buffer dielectric layer 121, the first material layers 123 and the second material layers 125 may be patterned to form channel holes 127 that penetrate the buffer dielectric layer 121, the first material layers 123 and the second material layers 125 to expose the substrate 110. The channel holes 127 may be arrayed along a first direction and a second direction. For example, the channel holes 127 may be disposed in a matrix form, when viewed from a plan view. The first direction and the second direction may be parallel with a top surface of the substrate 110 and may cross each other.

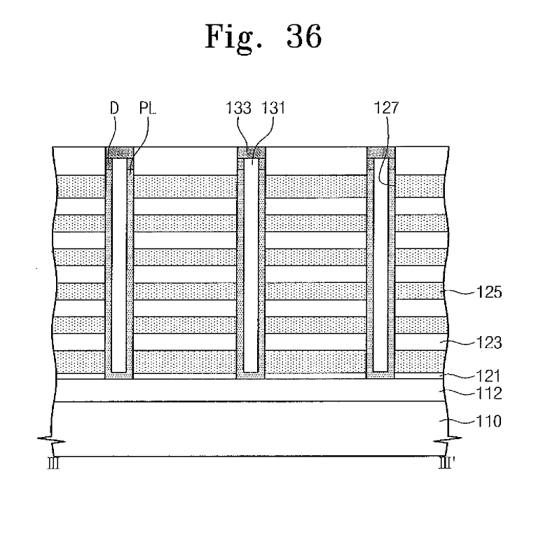

Referring to FIG. 36, active pillars PL may be formed in respective ones of the channel holes 127. The active pillars PL may be connected to the substrate 110. An exemplary method of forming the active pillars PL will now be described in detail hereinafter. First, a channel semiconductor layer of the first conductivity type may be formed in the channel holes 127. In an exemplary embodiment, the channel semiconductor layer may be conformally formed and need not fill the channel holes 127. An insulation layer is formed on the channel semiconductor layer to fill the channel holes 127. The insulation layer and the channel semiconductor layer may be planarized to expose the uppermost first material layer 123. As a result, a cylinder-shaped active pillar PL and a filling insulation layer 131 surrounded by the cylinder-shaped active pillar PL may be formed in each of the channel holes 127. Alternatively, the channel semiconductor layer may be formed to completely fill the channel holes 127. In this case, the process for forming the insulation layer may be omitted.

Top surfaces of the active pillars PL may be lower level than a top surface of the uppermost first material layer 123. Capping semiconductor patterns 133 may be formed on the active pillars PL and fill respective ones of the channel holes 127. Impurity ions of a second conductivity type may be implanted into upper portions of the active pillars PL to form drain regions D. While the drain regions D are formed, the impurity ions of the second conductivity type may also be implanted and/or diffused in the capping semiconductor patterns 133. Thus, the drain regions D may be formed to extend into the capping semiconductor patterns 133.

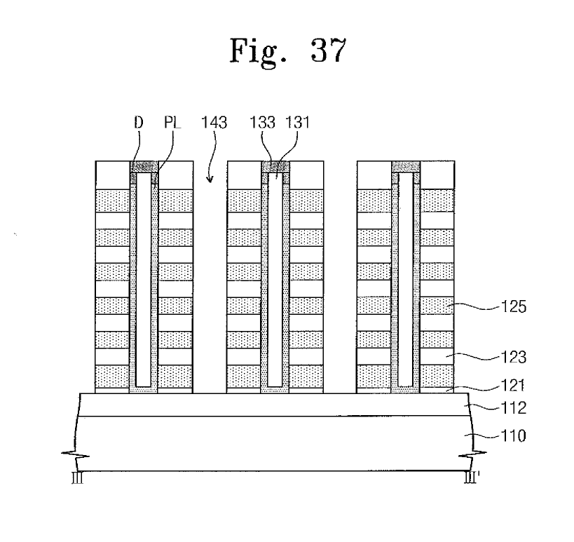

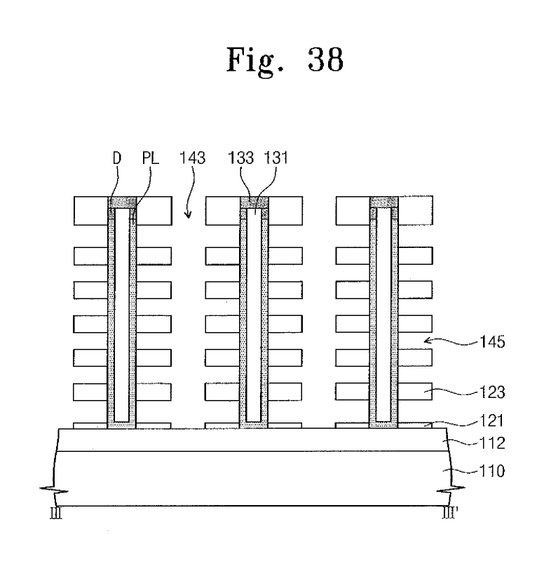

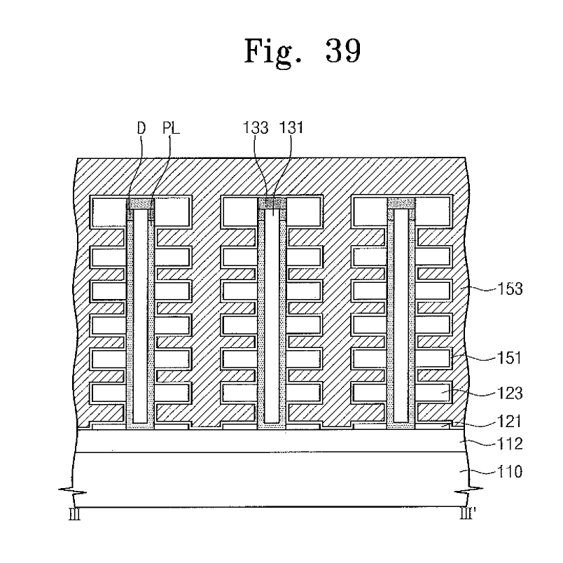

Referring to FIGS. 37 and 38, the first and second material layers 123 and 125 may be patterned to form grooves 143 spaced apart from each other. Each of the grooves 143 may be formed between two adjacent active pillars PL and may extend in the first direction.

The second material layers 125 exposed by the grooves 143 may be selectively removed to form empty spaces 145. For example, the empty spaces 145 may correspond to regions that the second material layers 125 are removed. When each of the second material layers 125 includes a silicon nitride layer, the second material layers 125 may be removed using an etchant including phosphoric acid (H3PO4). The empty spaces 145 may expose portions of sidewalls of the active pillars PL.

Referring to FIG. 39, a data storage layer 151 may be conformally formed on the resulting structure of FIG. 38. For example, the data storage layer 151 is formed in the empty spaces 145. The data storage layer 151 may include a tunnel insulation layer contacting the active pillars PL, a charge storage layer disposed on the tunnel insulation layer, and a blocking insulation layer disposed on the charge storage layer. The tunnel insulation layer may include a silicon oxide layer. The tunnel insulation layer may be formed by thermally oxidizing the active pillars PL exposed by the empty spaces 145. Alternatively, the tunnel insulation layer may be formed using an atomic layer deposition (ALD) process. The charge storage layer may be an insulation layer including a charge trap layer or conductive nano dots. The charge trap layer may include a silicon nitride layer. The blocking insulation layer may include a high-k dielectric layer (e.g., an aluminum oxide layer or a hafnium oxide layer). The blocking insulation layer may include a laminated layer including a plurality of thin films. For example, the blocking insulation layer may include an aluminum oxide layer and a silicon oxide layer. The stack order of the aluminum oxide layer and the silicon oxide layer may be various. The charge storage layer and the blocking insulation layer may be formed using an atomic layer deposition (ALD) process and/or a chemical vapor deposition (CVD) process having a good step coverage characteristic.

A gate conductive layer 153 may be formed on the data storage layer 151. The gate conductive layer 153 is formed to fill the empty spaces 145 surrounded by the data storage layer 151. Further, the gate conductive layer 153 may be formed to fill the grooves 143 partially or completely. The gate conductive layer 153 may include at least one of a doped silicon layer, a tungsten layer, a metal nitride layer and a metal silicide layer. The gate conductive layer 153 may be formed using an atomic layer deposition (ALD) process.

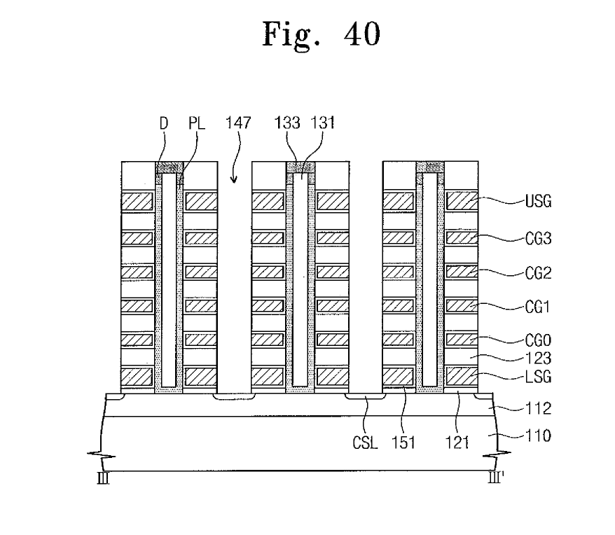

Referring to FIG. 40, the gate conductive layer 153 formed outside the empty spaces 145 may be removed to form gates in empty spaces 145. The gates may include upper selection gates USG, control gates CG0-CG3, lower selection gates LSG. The upper selection gates USG may be spaced apart from each other by isolation region 147 corresponding to the grooves 143 and may be arrayed in the second direction. The control gates CG0, CG1, CG2 or CG3 may also be spaced apart from each other by the isolation region 147 and may be arrayed in the second direction. Similarly, the lower selection gates LSG may be spaced apart from each other by the isolation region 147 and may be arrayed in the second direction. The gate conductive layer 153 in the grooves 143 may be removed to expose the substrate 110. Impurity ions of the second conductivity type may be implanted into the exposed substrate 110 to form common source lines CSL under the grooves 143. The first material layers 123 between the gates USG, CG0-CG3 and LSG may serve as inter-gate insulation layers. The first material layers 123 may be referred to as inter-gate insulation layers.

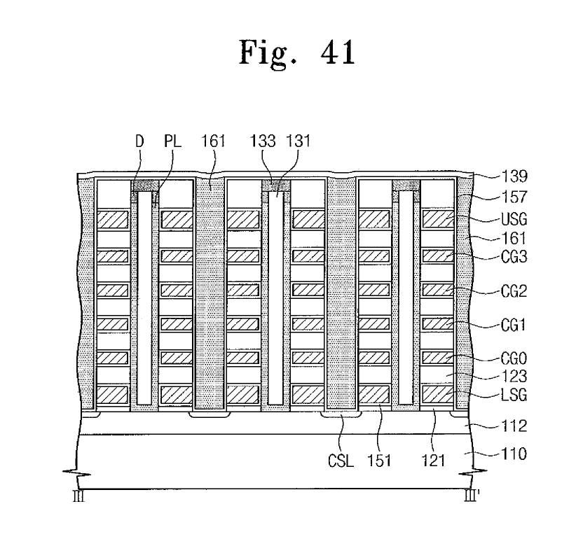

Referring to FIG. 41, a capping layer 157 may be formed to cover the gates USG, CG0-CG3 and LSG and the inter-gate insulation layers 123. The capping layer 157 may include a silicon oxide layer formed using a CVD process or an ALD process. A preliminary sacrificial layer may be formed to fill the isolation region 147 using substantially the same method described with reference to FIG. 5. The preliminary sacrificial layer may be planarized to expose the capping layer 157 on the uppermost first material layer 123, thereby forming a sacrificial layer 161. The planarization process may be performed using a chemical mechanical polishing (CMP) process. A porous insulation layer 139 is formed on the substrate including the planarized sacrificial layer 161. The porous insulation layer 139 may include a plurality of pores penetrating the porous insulation layer 139. The porous insulation layer 139 may be formed using substantially the same method described with reference to FIG. 6.

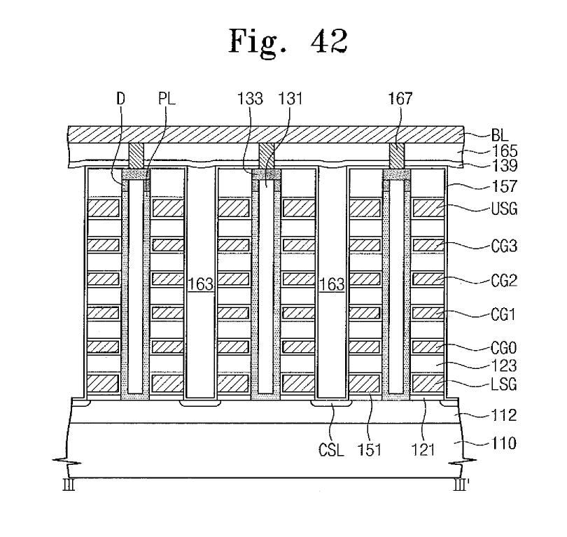

Referring to FIG. 42, the sacrificial layer 161 may be selectively removed through the pores of the porous insulation layer 139. For example, a chemical gas or a wet etchant penetrating the porous insulation layer 139 via the pores may remove the sacrificial layer 161. The sacrificial layer 161 may be selectively removed using substantially the same method as described with reference to FIG. 7. Thus, air gaps 163 may be formed in the isolation region (147 of FIG. 40) and thus are surrounded by the capping layer 157 and the porous insulation layer 139. Each of the air gaps 163 may include an empty space surrounded by the substrate 110, the gates LSG, CG0-3, and USG, the inter-gate insulation layers 123 and the porous insulation layer 139. The air gaps 163 may extend along the first direction and may separate the gates LSG, CG0-3, and USG, which are laterally adjacent to each other in the second direction.

An interlayer insulation layer 165 may be formed on the porous insulation layer 139. The interlayer insulation layer 165 may include a silicon oxide layer. Conductive pillars 167 may be formed to penetrate the interlayer insulation layer 165 and the porous insulation layer 139. The conductive pillars 167 may contact respective ones of the capping semiconductor patterns 133. Bit lines BL may be formed on the interlayer insulation layer 165 and may extend parallel to the second direction. The bit lines BL may be formed to contact the conductive pillars 167.

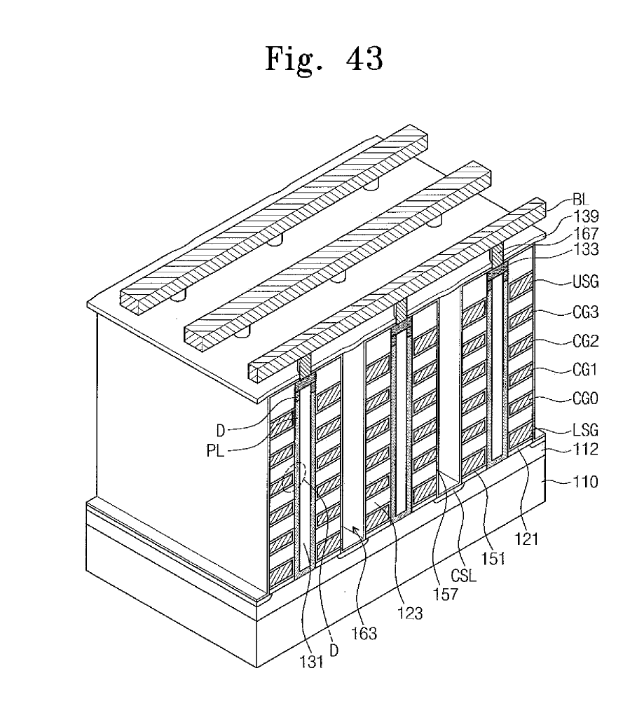

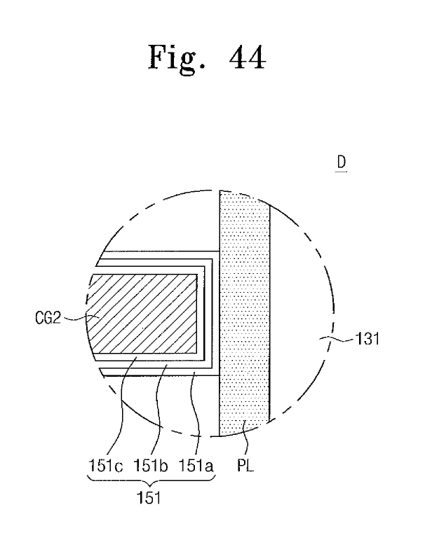

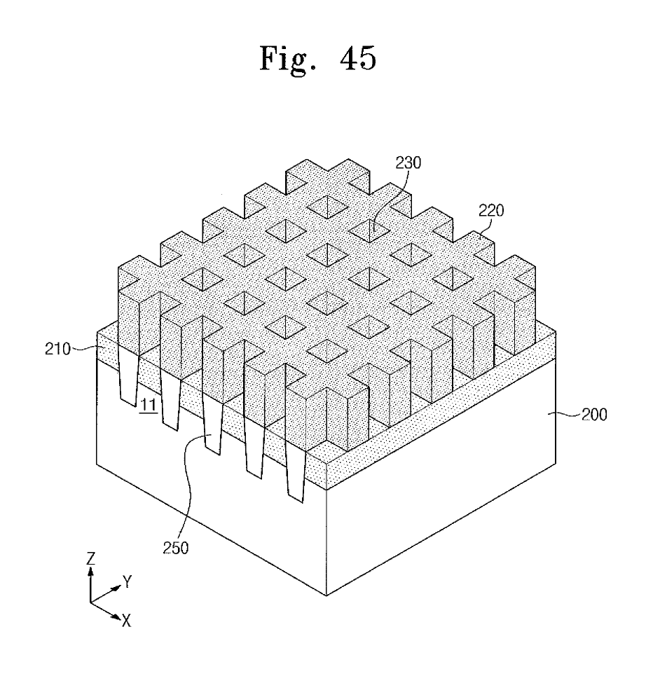

FIG. 43 is a perspective view illustrating a semiconductor device fabricated by an exemplary embodiment of the inventive concept. FIG. 44 is an enlarged view of a portion D of FIG. 43.

Referring to FIGS. 43 and 44, a buffer dielectric layer 121 may be formed on a substrate 110. A well region 112 of a first conductivity type may be formed in an upper portion of the substrate 110. A top surface of the well region 112 may correspond to a top surface of the substrate 110. The buffer dielectric layer 121 may include a silicon oxide layer. A plurality of inter-gate insulation layers 123 and a plurality of gates LSG, CG0-3, and USG may be alternately stacked on the buffer dielectric layer 121.

The gates LSG, CG0-3, and USG may include lower selection gates LSG, upper selection gates USG, and control gates CG0-CG3 between the lower selection gates LSG and the upper selection gates USG. Each of the gates LSG, CG0-CG3 and USG may have a line shape extending in a first direction. Each of the gates LSG, CG0-CG3 and USG may include at least one of a doped silicon layer, a tungsten layer, a metal nitride layer and a metal silicide layer.

A plurality of active pillars PL may penetrate the gates LSG, CG0-CG3 and USG to be connected to the substrate 110. Each of the active pillars PL may extend along a vertical major axis, which is perpendicular to the top surface of the substrate 110. Each of the active pillars PL may include a semiconductor material. Each of the active pillars PL may have a vertical bar shape without any empty space therein or a cylindrical shape with an empty space therein (e.g., a macaroni shape). When each of the active pillars PL has the macaroni shape, the inner empty space of each of the active pillars PL may be filled with a filling insulation layer 131. The active pillars PL and the substrate 110 may constitute a single unified semiconductor that has a continuous structure without any heterogeneous junction therebetween. Each of the active pillars PL may include a single crystalline semiconductor. In an exemplary embodiment, a discontinuous interface may exist between each of the active pillars PL and the substrate 110. For example, a heterogeneous junction may exist between each of the active pillars PL and the substrate 110. Each of the active pillars PL may include a poly crystalline semiconductor or an amorphous semiconductor. Each of the active pillars PL may include a body contacting the substrate 110, and a drain region D disposed on an upper end of the body to be spaced apart from the substrate 110. The bodies of the active pillars PL may have the first conductivity type, and the drain regions D of the active pillars PL may have a second conductivity type different from the first conductivity type.

One end (e.g., the body) of each of the active pillars PL may be connected to the substrate 110, and the other end (e.g., the drain D) of each of the active pillars PL may be connected to one of bit lines BL. The bit lines BL may extend in a second direction intersecting the first direction. Each of the active pillars PL may be electrically connected to one of the bit lines BL, and each of the bit lines BL may be electrically connected to a plurality of cell strings. The active pillars PL may be arrayed along the first direction and the second direction. For example, the active pillars PL may be disposed in a matrix form, when viewed from a plan view. Thus, intersections of the control gates CG0-CG3 and the active pillars PL may be three dimensionally disposed. Memory cells of the semiconductor device according to an exemplary embodiment may be formed at the intersections of the control gates CG0-CG3 and the active pillars PL, which are three dimensionally disposed. For example, each of the memory cells may be configured to include one of the active pillars PL and one of the control gates surrounding the active pillar PL.

A data storage layer 151 may be formed between the control gates CG0-CG3 and the active pillars PL. The data storage layer 151 may extend onto top surfaces and bottom surfaces of the gates LSG, CG0-CG3 and USG. The data storage layer 151 may include a blocking insulation layer 151c adjacent to the control gates CG0-CG3, a tunnel insulation layer 151a adjacent to the active pillars PL, and a charge storage layer 151b therebetween. The blocking insulation layer 151c may include a high-k dielectric layer (e.g., an aluminum oxide layer or a hafnium oxide layer). The blocking insulation layer may include a laminated layer including a plurality of thin films. For example, the blocking insulation layer may include an aluminum oxide layer and a silicon oxide layer. The stack order of the aluminum oxide layer and the silicon oxide layer may be various. The charge storage layer 151b may include an insulation layer including a charge trap layer or conductive nano dots. The charge trap layer may include a silicon nitride layer. The tunnel insulation layer may include a silicon oxide layer.

A capping layer 157 may be disposed to cover the gates USG, CG0-CG3 and LSG and the inter-gate insulation layers 123. The capping layer 157 may include, for example, a silicon oxide layer. A porous insulation layer 139 may be formed on the capping layer 157. The capping layer 157 may be formed on the drain regions D. The porous insulation layer 139 may laterally extend to cover empty spaces 163 between the gates LSG, CG0-3, and USG. A bottom surface of the porous insulation layer 139 over the empty spaces 163 between the gates LSG, CG0-3, and USG laterally adjacent to each other may be lower than a bottom surface of the porous insulation layer 139 on the capping layer 157.

Air gaps 163 may correspond to the empty spaces 163. For example, the air gaps 163 may be between the gates LSG, CG0-3, and USG laterally adjacent to each other and under the porous insulation layer 139. Each of the air gaps 163 may correspond to the empty space surrounded by a top surface of the substrate 110, sidewalls of the gates, sidewalls of the inter-gate insulation layers 123, and a bottom surface of the porous insulation layer 139. The air gaps 163 may extend in the first direction and may separate the gates, which are laterally adjacent to each other.

An interlayer insulation layer 165 may be formed on the porous insulation layer 139. The interlayer insulation layer 165 may include a silicon oxide layer. Conductive pillars 167 may be formed to penetrate the interlayer insulation layer 165 and the porous insulation layer 139. The conductive pillars 167 may be electrically connected to respective ones of the capping semiconductor patterns 133. Bit lines BL extending in the second direction may be disposed on the interlayer insulation layer 165. The bit lines BL may be electrically connected to the conductive pillars 167.

The semiconductor device according to the an exemplary embodiment may be a NAND-type flash memory device including a plurality of cell strings, and each of the cell strings may include a plurality of memory cells formed on each active pillar.

According to an exemplary embodiment, the air gaps 163 filled with air may have a dielectric constant lower than a dielectric constant of a silicon oxide layer. Thus, the air gaps 163 may significantly reduce the parasitic capacitance between gates laterally adjacent to each other. Accordingly, the air gaps 163 may reduce data disturbance between memory cells adjacent to the air gaps 163.

FIGS. 45 through 48 are perspective views illustrating a method of fabricating a semiconductor device according to an exemplary embodiment of the inventive concept.

Referring to FIG. 45, device isolation patterns 250 may be formed in a semiconductor substrate 200 to define active regions. In an exemplary embodiment, each of the device isolation patterns 250 may be a line-shaped pattern extending along y direction. Accordingly, the active regions of the semiconductor substrate 200 may have a line-shaped structure in a plan view.

In an exemplary embodiment, before or after the formation of the device isolation patterns 250, lower wires 210 may be formed on the active regions, respectively, of the semiconductor substrate 200. Each of the lower wires 210 may be formed to have a line-shaped structure extending along y direction. The lower wires 210 may be formed between the device isolation patterns 250.

In an exemplary embodiment, the lower wires 210 may be impurity regions, which may be formed by doping the semiconductor substrate 200 with impurities. The lower wires 210 may be formed to have a different conductivity type from that of the semiconductor substrate 200. For example, in the case where the semiconductor substrate 200 is doped with p-type impurities, the lower wires 210 may be heavily doped with n-type impurities. Alternatively, the lower wires 210 may include a metal layer.

Referring to FIG. 45, a mold pattern 220 may be formed on the semiconductor substrate 200 and have openings 230 arranged in a matrix shape. In a plan view, the mold pattern 220 may be formed to have a grid or mesh shape. The openings 230 of the mold pattern 220 may be formed to expose the lower wire 210. Alternatively, the mold pattern 220 may be formed to expose the semiconductor substrate 200.

The mold pattern 220 may be formed by forming a mold layer on the semiconductor substrate 200 and patterning the mold layer. The mold pattern 220 may be formed in a substantially similar manner as forming the first sacrificial layer 40 described with reference to FIG. 5. For example, the mold pattern 220 may include a SOH layer or an amorphous carbon layer. The SOH layer may include a carbon-based SOH layer or a silicon-based SOH layer.

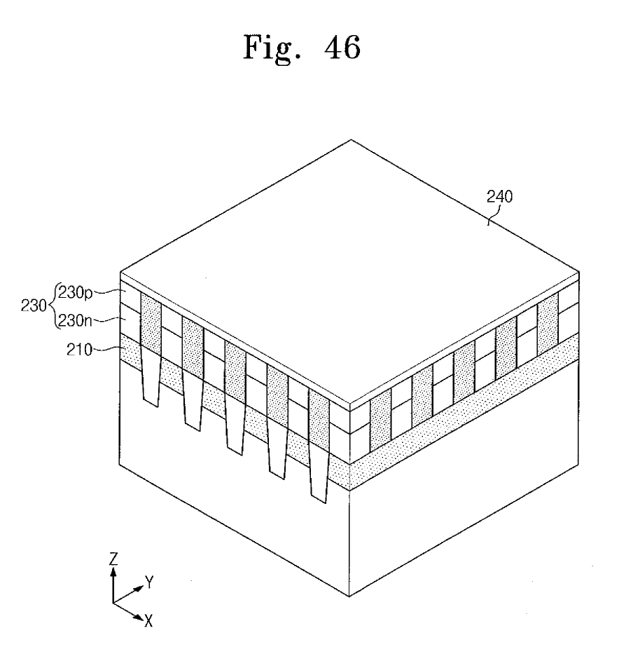

Referring to FIG. 46, semiconductor patterns 230 may be fanned to fill the openings 230 of the mold pattern 220.

In an exemplary embodiment, the semiconductor patterns 230 may be formed using a selective epitaxial growth (SEG) process, in which the semiconductor substrate 200 exposed by the mold pattern 220 is used as a seed layer. As the result of the selective epitaxial growth process, the semiconductor patterns 230 may be formed to have a single crystalline structure.

Each of the semiconductor patterns 230 may include an upper impurity region 230p and a lower impurity region 230n having a different conductivity type from that of the upper impurity region 230p. For example, the lower impurity region 230n may have the same conductivity type as the lower wires 210. The upper impurity region 230p may have a different conductivity type from the lower impurity region 230n. Thus, each of the semiconductor patterns 230 may be configured to include a p-n junction between an upper impurity region 230p and a lower impurity region 230n. Alternatively, an intrinsic region may be interposed between the upper impurity region 230p and the lower impurity region 230n, and in this case, a p-i-n junction may be formed in each of the semiconductor patterns 230. Alternatively, the semiconductor substrate 200, the lower wire 210 and the semiconductor pattern 230 may be configured to constitute a pnp or npn bipolar transistor.

Thereafter, a porous insulating layer 240 may be formed on the semiconductor patterns 230 and the mold pattern 220.

The porous insulating layer 240 may include a low-l dielectric layer having a plurality of pores therein, as described with reference to FIG. 6. The porous insulating layer 240 may be formed by, for example, forming a carbon-doped silicon oxide layer and performing a thermal treatment process thereon. The porous insulating layer 240 may include a plurality of pores whose a size or a diameter ranges from several ten nanometers to several hundred nanometers.

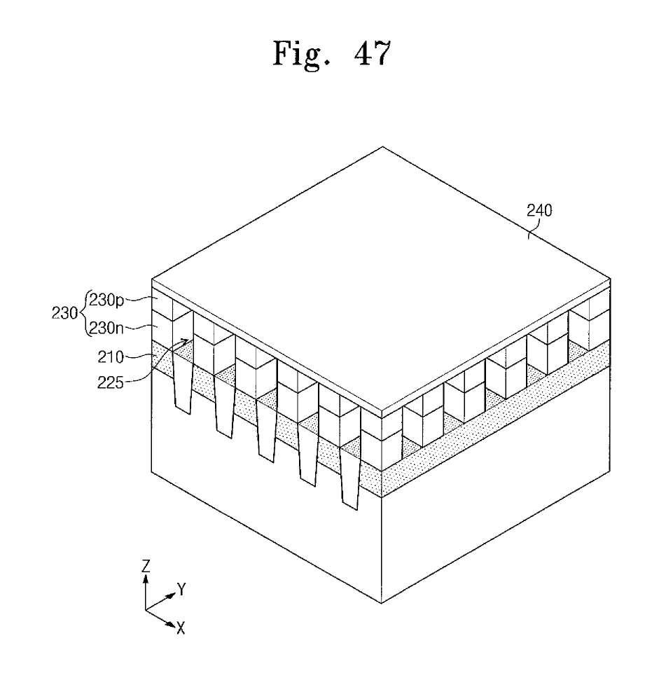

The mold pattern 220 may be removed using the pores of the porous insulating layer 240. In the case where the mold pattern 220 includes a SOH layer, the mold pattern 220 may be removed using an ashing process, in which oxygen, ozone, or UV light is used, or using a wet cleaning process, as described with reference to FIG. 7. As a result, as shown in FIG. 47, an air gap 225 may be formed between the semiconductor patterns 230 two-dimensionally arrange on the semiconductor substrate 200. The air gap 225 may reduce electrical interference between the semiconductor patterns 230.

After the formation of the air gap 225, a thermal treatment process may be performed to the porous insulating layer 240. As the result of the thermal treatment process, the size or the number of the pores may be reduced, thereby the porous insulating layer 240 having an increased density.

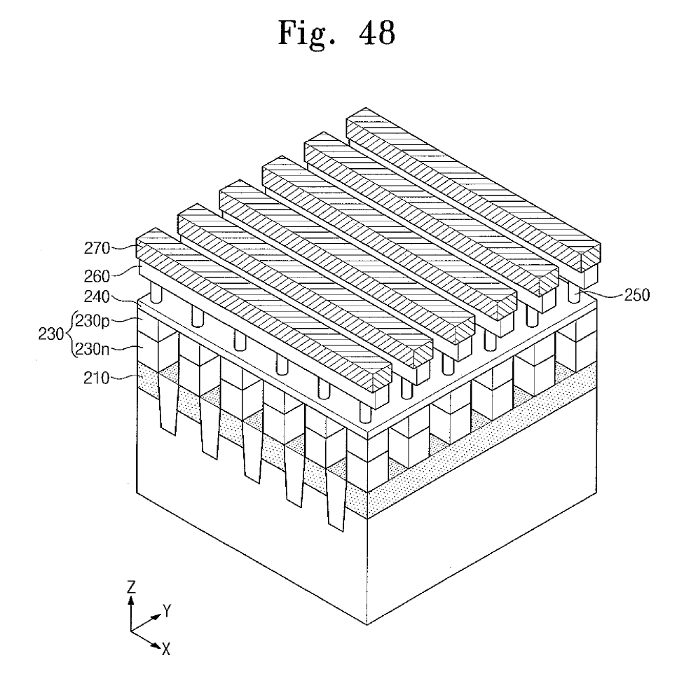

Referring to FIG. 48, lower electrodes 250 may penetrate the porous insulating layer 240 to be electrically connected to the semiconductor patterns 230. In an exemplary embodiment, each of the lower electrodes 250 may be shaped like a pillar. The inventive concept is not limited thereto, and the lower electrodes 250 may have various shapes to reduce a section area of the lower electrode 250. For example, the lower electrodes 250 may be formed to have a 3-D structure, such as a “U”-shaped structure, an “L”-shaped structure, a hollow-cylindrical structure, a ring-shaped structure, and/or a cup-shaped structure.

The lower electrodes 250 may include at least one material of metal nitrides, and metal oxynitrides including carbon (C), titanium (Ti), tantalum (Ta), aluminum titanium (TiAl), zirconium (Zr), hafnium (Hf), molybdenum (Mo), aluminum (Al), aluminum-copper (Al—Cu), aluminum-copper-silicon (Al—Cu—Si), copper (Cu), tungsten (W), tungsten titanium (TiW), or tungsten silicide (WSix). Here, the metal nitrides may include at least one of TiN, TaN, WN, MoN, NbN, TiSiN, TiAlN, TiBN, ZrSiN, WSiN, WBN, ZrAlN, MoSiN, MoAlN, TaSiN, and TaAlN. The metal oxynitrides may include at least one of TiON, TiAlON, WON, and TaON.

Memory elements 260 and upper interconnection lines 270 may be formed on the lower electrodes 250.

The memory elements 260 may have a line-shaped structure crossing the lower wires 210. Alternatively, the memory elements 260 may be formed parallel to the lower wires 210. In an exemplary embodiment, the memory elements 260 may be two-dimensionally arranged on the semiconductor substrate 200 and may be disposed on a corresponding one of the semiconductor patterns 230.

In an exemplary embodiment, the memory elements 260 may include a material having variable electrical resistances. The electrical resistance of the material may be controlled to have different resistances by changing an amount of electric current flowing therethrough. For example, the memory elements 260 may include chalcogenides, whose electrical resistance may be selectively changed by Joule heating in the memory elements. The chalcogenide may include at least one of antimony (Sb), tellurium (Te), and selenium (Se).

In an exemplary embodiment, the memory elements 260 may be formed to have a layer structure, whose electrical resistance may be selectively changed using a spin-torque transferring effect of electrons flowing therethrough. For example, the memory elements 260 may have a layer structure configured to exhibit a magneto-resistance property and including at least one ferromagnetic material and/or at least one antiferromagnetic material. In an exemplary embodiment, the memory elements 260 may include at least one of perovskite compounds and transition metal oxides.

The upper interconnection lines 270 may be formed on the memory elements 260 to cross the lower wires 210 (e.g., parallel to an x direction). In an exemplary embodiment, the upper interconnection lines 270 may be formed parallel to the memory elements 260.

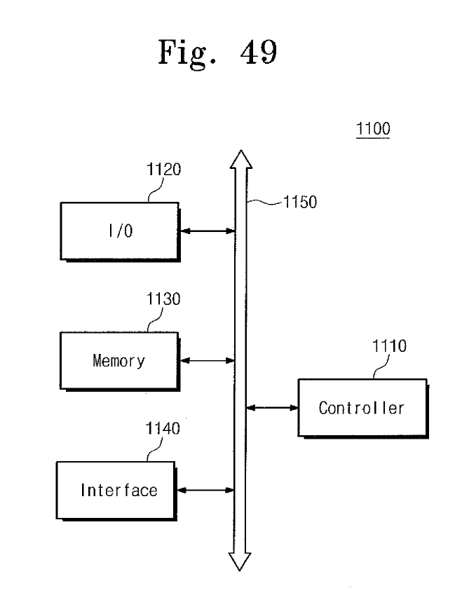

FIG. 49 is a schematic block diagram illustrating an example of electronic systems including a semiconductor device according to an exemplary embodiment of the inventive concept.

Referring to FIG. 49, an electronic system 1100 according to an exemplary embodiment of the inventive concept may include a controller 1110, an input/output (I/O) unit 1120, a memory device 1130, an interface unit 1140 and a data bus 1150. At least two of the controller 1110, the I/O unit 1120, the memory device 1130 and the interface unit 1140 may communicate with each other through the data bus 1150. The data bus 1150 may correspond to a signal path through which electrical signals are transmitted. The controller 1110, the input-output unit 1120, the memory device 1130, and/or the interface 1140 may be configured to include one of semiconductor devices according to an exemplary embodiment of the inventive concept.

The controller 1110 may include at least one of a microprocessor, a digital signal processor, a microcontroller and another logic device. The other logic device may have a similar function to any one of the microprocessor, the digital signal processor and the microcontroller. The I/O unit 1120 may include a keypad, a keyboard or a display unit. The memory device 1130 may store data and/or commands. The interface unit 1140 may transmit electrical data to a communication network or may receive electrical data from a communication network. The interface unit 1140 may operate in a wireless or cable-connected mode. For example, the interface unit 1140 may include an antenna for wireless communications or a transceiver for cable communications. The electronic system 1100 may further include a fast dynamic random access memory (DRAM) device and/or a fast static random access memory (SRAM) device that serves as a cache memory for increasing operation speeds of the controller 1110.

The electronic system 1100 may be applied to a personal digital assistant (PDA), a portable computer, a web tablet, a wireless phone, a mobile phone, a digital music player, a memory card or an electronic product. The electronic product may receive or transmit information data wirelessly.

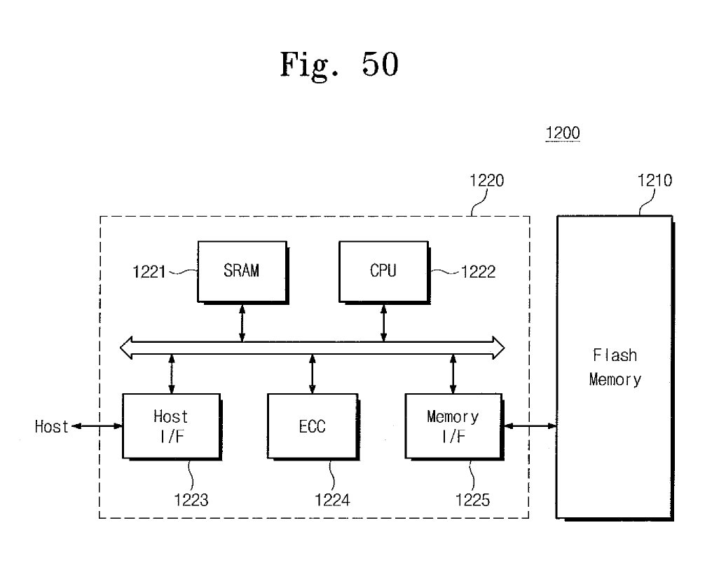

FIG. 50 is a block diagram illustrating an exemplary memory card including a semiconductor memory device according to an exemplary embodiment of the inventive concept.

Referring to FIG. 50, a memory card 1200 according to an exemplary embodiment of the inventive concept may include a memory device 1210. The memory device 1210 may include a semiconductor memory device according to an exemplary embodiment of the inventive concept. In an exemplary embodiment, the memory device 1210 may a plurality types of semiconductor memory devices according to an exemplary embodiment of the inventive concept. For example, the memory device 1210 may include a nonvolatile memory device and/or a static random access memory (SRAM) device. The memory card 1200 may include a memory controller 1220 that controls data communication between a host and the memory device 1210. The memory device 1210 and/or the memory controller 1220 may be integrated in a semiconductor device according to an exemplary embodiment of the inventive concept.

The memory controller 1220 may include a central processing unit (CPU) 1222 that controls overall operations of the memory card 1200. The memory controller 1220 may include an SRAM device 1221 used as an operation memory of the CPU 1222. The memory controller 1220 may also include a host interface unit 1223 and a memory interface unit 1225. The host interface unit 1223 may be configured to operate based on a data communication protocol between the memory card 1200 and the host. The memory interface unit 1225 may connect the memory controller 1220 to the memory device 1210. The memory controller 1220 may also include an error check and correction (ECC) block 1224. The ECC block 1224 may detect and correct errors of data which are read out from the memory device 1210. The memory card 1200 may also include a read only memory (ROM) device that stores code data necessary to operate the host. The memory card 1200 may be used as a portable data storage card. Alternatively, the memory card 1200 may be provided in the form of solid state disks (SSD).

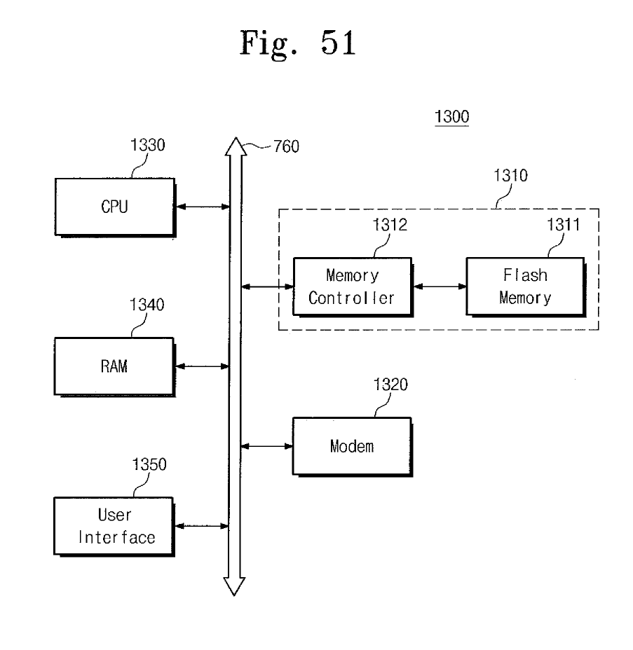

FIG. 51 is a block diagram illustrating an example of information processing systems including a semiconductor device according to an exemplary embodiment of the inventive concept.

Referring to FIG. 51, an information processing system 1300 includes a memory system 1310, which may include at least one of the semiconductor devices according to an exemplary embodiment of the inventive concept. The information processing system 1300 also includes a modem 1320, a central processing unit (CPU) 1330, a RAM 1340, and a user interface 1350, which may be electrically connected to the memory system 1310 via a system bus 760. The memory system 1310 may include a memory device 1311 and a memory controller 1312 controlling an overall operation of the memory device 1311. Data processed by the CPU 1330 and/or input from the outside may be stored in the memory system 1310. Here, the memory system 1310 may constitute a solid state drive SSD to store a large amount of data in the memory system 1310. Accordingly, the memory system 1310 may conserve resources for error correction and exchange data at a high speed. Although not shown in the drawing, it will be apparent to those of ordinary skill in the art that the information processing system 1300 may be also configured to include an application chipset, a camera image processor (CIS), and/or an input/output device.

The semiconductor devices disclosed above may be encapsulated using a packaging technology. For example, a semiconductor device according to an exemplary embodiment may be encapsulated using any one of a package on package (POP) technique, a ball grid arrays (BGAs) technique, a chip scale packages (CSPs) technique, a plastic leaded chip carrier (PLCC) technique, a plastic dual in-line package (PDIP) technique, a die in waffle pack technique, a die in wafer form technique, a chip on board (COB) technique, a ceramic dual in-line package (CERDIP) technique, a plastic quad flat package (PQFP) technique, a thin quad flat package (TQFP) technique, a small outline package (SOIC) technique, a shrink small outline package (SSOP) technique, a thin small outline package (TSOP) technique, a system in package (SIP) technique, a multi-chip package (MCP) technique, a wafer-level fabricated package (WFP) technique and a wafer-level processed stack package (WSP) technique.

According to an exemplary embodiment of the inventive concept, a semiconductor device may include a porous insulating layer covering an air gap disposed between active regions. The porous insulating layer may extend between a charge storing pattern and a gate electrode. Since the air gap has a dielectric constant of about 1, a parasitic capacitance between the active regions may be reduced, and thus, performance of the semiconductor device may be increased.

In a nonvolatile memory device provided with a floating gate electrode, a coupling ratio between floating and control gate electrodes may be increased by increasing a height difference between top surfaces of the porous insulating layer and the floating gate electrode. Accordingly, electric characteristics of the nonvolatile memory device may be increased.

While the present inventive concepts has been shown and described with reference to exemplary embodiments thereof, it will be apparent to those of ordinary skill in the art that various changes in form and detail may be made therein without departing from the spirit and scope of the inventive concept as defined by the following claims.

1. A semiconductor device, comprising:
a semiconductor substrate having a plurality of active regions defined by a trench;
a gate electrode crossing the plurality of active regions;
a plurality of charge storing cells between the gate electrode and each of the plurality of active regions; and
a porous insulating layer between the gate electrode and the plurality of charge storing cells, the porous insulating layer including a portion extended over the trench; and
an air gap disposed between the extended portion of the porous insulating layer and a bottom surface of the trench.

2. The device of claim 1, wherein the porous insulating layer is in direct contact with a top surface of each of the plurality of charge storing cells.

3. The device of claim 1, wherein the porous insulating layer is further disposed on the plurality of active regions and is in direct contact with a bottom surface of the gate electrode.

4. The device of claim 1, wherein, in a region between the active regions, a bottom surface of the porous insulating layer is located between top and bottom surfaces of each of the plurality of charge storing cells.

5. The device of claim 4, wherein the porous insulating layer has a uniform thickness on the active region and the trench.

6. The device of claim 4, wherein the gate electrode further fills a gap region between two adjacent charge storing cells of the plurality of charge storing cells.

7. The device of claim 4, further comprising:
an inter-gate insulating layer disposed between the porous insulating layer and the gate electrode and conformally covering the porous insulating layer.

8. The device of claim 7, wherein the porous insulating layer includes a material having an etch rate greater than an etch rate of the inter-gate insulating layer in a wet etching process using a 200:1 dilute HF solution.

9. The device of claim 1, wherein the porous insulating layer includes p-SiCOH.

10. The device of claim 1, wherein the porous insulating layer includes an insulating material having an etch rate of about 100 to 200 Å/min in a wet etching process using a 200:1 dilute HF solution.

11. The device of claim 1, wherein each of the charge storing cells comprises a tunnel insulating layer and a floating gate pattern sequentially stacked on the semiconductor substrate.

12. The device of claim 1, wherein in a region between two active regions of the plurality of active regions, a bottom surface of the porous insulating layer is higher than a top surface of the charge storing pattern disposed on the active region.

13. The device of claim 1, wherein the charge storing pattern comprises a tunnel insulating layer, a charge trap layer, and a blocking insulating layer sequentially stacked on the semiconductor substrate.

14. The device of claim 1, further comprising:
an insulating gap-filling pattern filling a lower portion of the trench and having a top surface lower than a top surface of the semiconductor substrate,
wherein the air gap is defined by a bottom surface of the porous insulating layer and a top surface of the insulating gap-filling pattern.

15. The device of claim 1, further comprising:
an insulating liner conformally covering an inner surface of the trench.

16. A semiconductor device, comprising:
a semiconductor substrate having a trench;
a porous insulating layer disposed on the semiconductor substrate, the porous insulating layer extending over the trench to define an air gap in the trench underneath the porous insulating layer; and
a gate electrode disposed on the porous insulating layer.

17. The device of claim 16, further comprising:
a charge storing cell interposed between the porous insulating layer and a top surface of the semiconductor substrate.

18. The device of claim 17, wherein a top surface of the porous insulating layer on the trench is lower than a top surface of the charge storing pattern.

19. The device of claim 17, wherein the porous insulating layer is in direct contact with a top surface of the charge storing pattern.

20. The device of claim 16, further comprising:
an insulating gap-filling pattern spaced apart from the porous insulating layer and filling a lower portion of the trench.

21. The device of claim 16, further comprising:
an insulating liner spaced apart from the porous insulating layer and conformally covering a lower portion of an inner surface of the trench.

22. A semiconductor device, comprising:
a semiconductor substrate including a plurality of lower wires extended in a first direction;
a plurality of semiconductor patterns disposed on each of the plurality of lower wires, wherein the plurality of semiconductor patterns is spaced apart from each other along the first direction;
a porous insulating layer disposed on top surfaces of the plurality of semiconductor patterns and covering an air gap between two adjacent semiconductor patterns of the plurality of semiconductor patterns;
a plurality of lower electrodes disposed on the porous insulating layer, wherein the plurality of lower electrodes respectively penetrates the porous insulating layer to be in contact with the plurality of semiconductor patterns; and
a plurality of memory elements respectively disposed on the plurality of lower electrodes, wherein each of the plurality of memory elements is extended in a second direction crossing the first direction.

23. The semiconductor device of claim 22, wherein each of the plurality of memory elements comprises a material whose electrical resistance is selectively changed.

24. The semiconductor device of claim 23, wherein each of the plurality of semiconductor patterns includes a p-n junction.

25. (canceled)

26. (canceled)

27. (canceled)

28. (canceled)

29. (canceled)

30. (canceled)

31. (canceled)

32. (canceled)

33. (canceled)

34. (canceled)

35. (canceled)

36. (canceled)

37. (canceled)

38. A semiconductor device, comprising:
a semiconductor substrate having a first trench and a second trench;
a first insulation layer disposed on the semiconductor substrate;
a first air gap disposed in the first trench and covered by a first porous insulation layer;
a second air gap disposed in the second trench and covered by the first porous insulation layer; and
a non-volatile memory cell disposed on an active region between the first trench and the second trench, wherein each of the first and second air gaps partially and laterally overlaps the non-volatile memory cell.

39. The semiconductor device of claim 38, wherein the first insulation layer includes a plurality of pores.

40. The semiconductor device of claim 38, wherein the first insulation layer includes p-SiCOH.

41. The semiconductor device of claim 38, wherein the first air gap has an upper surface higher than a top surface of the active region.

42. The semiconductor device of claim 38, wherein the non-volatile memory cell comprises a tunnel insulation pattern, a floating gate pattern, an inter-gate insulating layer and a control gate electrode, wherein the tunnel insulation pattern is disposed on active region, the floating gate pattern is disposed on the tunnel insulation pattern, the inter-gate insulating layer is disposed on the floating gate pattern and the control gate electrode is disposed on the inter-gate insulating layer, wherein the insulation layer is disposed between the floating gate pattern and the inter-gate insulating layer.

43. The semiconductor device of claim 42, wherein the control gate electrode is further disposed on the first and second air gaps so as to laterally overlap the floating gate pattern disposed on the active region.

44. The semiconductor device of claim 43, wherein the first air gap laterally overlaps the tunnel insulation layer and partially and laterally overlaps the floating gate pattern disposed on the active region.

45. The semiconductor device of claim 44, further comprising a second insulation layer disposed on the control gate electrode and the first and second air gaps, wherein the second insulation layer includes p-SiCOH.

46. The semiconductor device of claim 38, wherein the non-volatile memory cell comprises a gate electrode and a charge storing pattern comprising a tunnel insulating pattern, a charge trap pattern, and a blocking insulating pattern, wherein the tunnel insulation pattern is disposed on the active region between the first trench and the second trench, the charge trap pattern is disposed on the tunnel insulation pattern, the blocking insulating pattern is disposed on the charge trap pattern and the gate electrode is disposed on the blocking insulating pattern, wherein the first insulation layer is disposed between the gate electrode and the blocking insulation pattern.

47. The semiconductor device of claim 46, wherein the gate electrode is further disposed on the first and second air gaps.

48. The semiconductor device of claim 47, wherein each of the first and second air gaps laterally overlaps the charge storing pattern and partially and laterally overlaps the gate electrode.
